(19) United States
(12) Patent Application Publication
(10) Pub. No.: US 2016/0261233 A1
(43) Pub. Date: Sep. 8, 2016

(54) METHOD AND APPARATUS FOR WIRELESS POWER TRANSMISSION UTILIZING TWO-DIMENSIONAL OR THREE-DIMENSIONAL ARRAYS OF MAGNETO-MECHANICAL OSCILLATORS

(71) Applicant: QUALCOMM Incorporated, San Diego, CA (US)

(72) Inventors: Johan Pohl, Bad Saeckingen (DE); Hanspeter Widmer, Wohlenschwil (CH)

(21) Appl. No.: 14/635,947

(22) Filed: Mar. 2, 2015

(51) Int. Cl. H03B 15/00; H02J 7/02; H01F 38/14; H02J 5/00

(52) U.S. Cl. CPC H03B 15/00; H02J 5/005; H02J 7/025; H01F 38/14

(57) ABSTRACT

An apparatus for transferring power wirelessly is provided. The apparatus comprises a plurality of magneto-mechanical oscillators. Each oscillator comprises a first base support element disposed on a substrate, a first beam connected to the first base support element, a holder connected to the first beam, and a magnetic element disposed on the holder and configured to generate a first time-varying magnetic field in response to movement of the magnetic element under the influence of a second time-varying magnetic field. Each of the oscillators may comprise a second base support element disposed on the substrate and a second beam connecting the holder to the second base support element.

### FIELD

The present invention relates generally to wireless power transmission, and more specifically, to methods and apparatuses for wireless power transmission utilizing two- or three-dimensional arrays of magneto-mechanical oscillators.

### BACKGROUND

An increasing number and variety of electronic devices are powered via rechargeable batteries. Such devices include mobile phones, portable music players, laptop computers, tablet computers, computer peripheral devices, communication devices (e.g., Bluetooth devices), digital cameras, hearing aids, and the like. While battery technology has improved, battery-powered electronic devices increasingly require and consume greater amounts of power, thereby often requiring recharging. Rechargeable devices are often charged via wired connections through cables or other similar connectors that are physically connected to a power supply. Cables and similar connectors may sometimes be inconvenient or cumbersome and have other drawbacks. Wireless charging systems that are capable of transferring power in free space to be used to charge rechargeable electronic devices or provide power to electronic devices may overcome some of the deficiencies of wired charging solutions. As such, methods and apparatuses for wireless power transmission utilizing two- or three-dimensional arrays of magneto-mechanical oscillators are desirable.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides an apparatus for transferring power wirelessly. The apparatus comprises a plurality of magneto-mechanical oscillators. Each oscillator comprises a first base support element disposed on a substrate, a first beam connected to the first base support element, a holder connected to the first beam, and a magnetic element disposed on the holder. The magnetic element is configured to generate a first time-varying magnetic field in response to movement of the magnetic element under influence of a second time-varying magnetic field.

Another aspect of the disclosure provides a method of transferring power wirelessly. The method comprises generating a first time-varying magnetic field via movement of a magnetic element in each of a plurality of magneto-mechanical oscillators under the influence of a second time-varying magnetic field. The magnetic element is disposed on a holder connected to a first base support on a substrate by a first beam.

Another aspect of the disclosure provides a method for fabricating a plurality of magneto-mechanical oscillators. The method comprises providing a substrate. The method further comprises forming a first base support element on the substrate. The method further comprises forming a first beam connected to the first base support element. The method further comprises forming a holder connected to the first beam. The method further comprises depositing a magnetic element on the holder.

Another aspect of the disclosure provides a non-transitory computer-readable medium comprising code that, when executed, causes an apparatus to perform a method comprising generating a first time-varying magnetic field via movement of a magnetic element in each of a plurality of magneto-mechanical oscillators under the influence of a second time-varying magnetic field. The magnetic element is disposed on a holder connected to a first base support on a substrate by a first beam.

Another aspect of the disclosure provides an apparatus for transferring power wirelessly. The apparatus comprises means for generating a first time-varying magnetic field via movement of a magnetic element under the influence of a second time-varying magnetic field. The means for generating the first time-varying magnetic field is disposed on means for holding the means for generating the first time-varying magnetic field. The means for holding the means for generating the first time-varying magnetic field is connected to a first means for support by a first beam.

Another aspect of the disclosure provides an apparatus for transferring power wirelessly. The apparatus comprises a plurality of magneto-mechanical oscillators. Each oscillator comprises first and second base support elements, each disposed on a substrate, a first beam connected to the first support element, a first magnetic element connected to the first beam, and a second magnetic element. The first and second magnetic elements have a same direction of magnetization and are positioned such that an attraction between the first and second magnetic elements provides a restoring force to at least the first magnetic element. At least the first magnetic element is configured to generate a first time-varying magnetic field under the influence of a second time-varying magnetic field.

Another aspect of the disclosure provides a method of transferring power wirelessly. The method comprises generating a first time-varying magnetic field via movement of a first magnetic element in each of a plurality of magneto-mechanical oscillators under the influence of a second time-varying magnetic field. Each of the plurality of magneto-mechanical oscillators further includes a second magnetic element. A direction of magnetization is the same for the first magnetic element and the second magnetic element and the first and second magnetic elements are positioned such that attraction between the first and second magnetic elements provides a first restoring force to at least the first magnetic element.

Another aspect of the disclosure provides a method for fabricating a plurality of magneto-mechanical oscillators. The method comprises providing a substrate. The method further comprises forming first and second base support elements on the substrate. The method further comprises forming a first beam connected to the first base support element. The method further comprises forming a first magnetic element connected to the first beam and having a direction of magnetization. The method further comprises forming a second magnetic element having the direction of magnetization and a position such that an attraction between the first and second magnetic elements provides a first restoring force to at least the first magnetic element.

Another aspect of the disclosure provides a non-transitory computer-readable medium comprising code that, when executed, causes an apparatus to perform a method comprising generating a first time-varying magnetic field via movement of a first magnetic element in each of a plurality of magneto-mechanical oscillators under the influence of a second time-varying magnetic field. A direction of magnetization is the same for the first magnetic element and the second magnetic element and the first and second elements are positioned such that attraction between the first and second magnetic elements provides a first restoring force to at least the first magnetic element.

Another aspect of the disclosure provides an apparatus for transferring power wirelessly. The apparatus comprises means for generating a first time-varying magnetic field via movement of a first magnetic element under the influence of a second time-varying magnetic field. A direction of magnetization is the same for a first portion of the means for generating the second time-varying magnetic field and for a second portion of the means for generating the first time-varying magnetic field and the first and second portions are positioned such that attraction between the first and second portions provides a first restoring force to at least the first portion.

Another aspect of the disclosure provides an apparatus for transferring power wirelessly. The apparatus comprises a plurality of magneto-mechanical oscillators. Each oscillator comprises first and second base support elements disposed on a substrate, and a chain comprising a plurality of magnetic elements suspended between the first and second base support elements.

Another aspect of the disclosure provides a method of transferring power wirelessly. The method comprises generating a first time-varying magnetic field via movement of a plurality of magnetic elements arranged in a chain in each of a plurality of magneto-mechanical oscillators under the influence of a second time-varying magnetic field.

Another aspect of the disclosure provides a method for fabricating a plurality of magneto-mechanical oscillators. The method comprises forming first and second base support elements on a substrate. The method further comprises forming a chain suspended between the first and second base support elements. The chain comprises a plurality of magnetic elements.

Another aspect of the disclosure provides a non-transitory computer-readable medium comprising code that, when executed, causes an apparatus to perform a method comprising generating a first time-varying magnetic field via movement of a plurality of magnetic elements arranged in a chain in each of a plurality of magneto-mechanical oscillators under the influence of a second time-varying magnetic field.

Another aspect of the disclosure provides an apparatus for transferring power wirelessly. The apparatus comprises means for generating a first time-varying magnetic field via movement of a plurality of magnetic elements arranged in a chain under the influence of a second time-varying magnetic field.

### BRIEF DESCRIPTION OF THE DRAWINGS

FIG. 1 is a functional block diagram of a wireless power transfer system, in accordance with some exemplary implementations.

FIG. 2 is a functional block diagram of components that may be used in the wireless power transfer system of FIG. 1, in accordance with some exemplary implementations.

FIG. 3 is a schematic diagram of a portion of transmit circuitry or receive circuitry of FIG. 2 including a transmit or receive coupler.

FIG. 4 is a functional block diagram of a transmitter that may be used in the wireless power transfer system of FIG. 1, in accordance with some exemplary implementations.

FIG. 5 is a functional block diagram of a receiver that may be used in the wireless power transfer system of FIG. 1, in accordance with some exemplary implementations.

FIG. 6 is a schematic diagram of a portion of transmit circuitry that may be used in the transmitter of FIG. 4.

FIG. 7 illustrates non-radiative inductive power transfer based on Faraday's law using capacitively loaded wire loops at both the transmit and receive sides.

FIG. 8 schematically illustrates an example magneto-mechanical oscillator, in accordance with some exemplary implementations.

FIG. 9 schematically illustrates an example magneto-mechanical oscillator (e.g., a portion of a plurality of magneto-mechanical oscillators) with a coupling coil wound around (e.g., surrounding) the magneto-mechanical oscillator, in accordance with some exemplary implementations.

FIG. 10A schematically illustrates the parallel magnetic flux lines (B) inside a magnetized sphere.

FIG. 10B schematically illustrates the magnetic field strength (H) in a magnetized sphere.

FIG. 11 schematically illustrates an example array of magneto-mechanical oscillators fabricated using MEMS technology, in accordance with some exemplary implementations.

FIG. 12 schematically illustrates a cut through area of a three-dimensional array of magneto-mechanical oscillators, in accordance with some exemplary implementations.

FIG. 13 schematically illustrates an example coupling coil wound around a disk having a plurality of magneto-mechanical oscillators, in accordance with some exemplary implementations.

FIG. 14 schematically illustrates an example power transmitter configured to wirelessly transfer power to at least one power receiver, in accordance with some exemplary implementations.

FIG. 15 schematically illustrates an example power transmitter, in accordance with some exemplary implementations, and a plot of input impedance versus frequency showing a resonance phenomenon.

FIG. 16 schematically illustrates a portion of a configuration of a plurality of magneto-mechanical oscillators, in accordance with some exemplary implementations.

FIG. 17 schematically illustrates a configuration of the plurality of magneto-mechanical oscillators in which magnetic elements are pairwise oriented in opposite directions so that the static component of the sum magnetic moment cancels out, in accordance with some exemplary implementations.

FIG. 18 illustrates a torsional magnetic double hinge magneto-mechanical oscillator, in accordance with some exemplary implementations.

FIG. 19 illustrates a torsional magnetic double hinge magneto-mechanical oscillator, in accordance with some other exemplary implementations.

FIG. 20 illustrates a 2-dimensional nested array of the torsional magnetic double hinge oscillators of FIG. 18 and FIG. 19, in accordance with some exemplary implementations.

FIG. 21 illustrates a top view and a side view of a torsional magnetic single hinge magneto-mechanical oscillator, in accordance with some exemplary implementations.

FIG. 22 illustrates a 2-dimensional nested array of the torsional magnetic single hinge magneto-mechanical oscillator of FIG. 21, in accordance with some exemplary implementations.

FIG. 23 illustrates a torsional in-plane magneto-mechanical oscillator, in accordance with some exemplary implementations.

FIG. 24 illustrates a 2-dimensional array of the torsional in-plane magneto-mechanical oscillators of FIG. 23, in accordance with some exemplary implementations.

FIG. 25 illustrates a 3-dimensional array of the torsional magneto-mechanical oscillators of any of FIGS. 18-22, in accordance with some exemplary implementations.

FIG. 26 illustrates a 3-dimensional array of the torsional magneto-mechanical oscillators of any of FIGS. 18-22 and 25, in accordance with some exemplary implementations.

FIG. 27 illustrates a 3-dimensional array of the torsional magneto-mechanical oscillators of any of FIGS. 18-22 and 25, in accordance with some exemplary implementations.

FIG. 28 illustrates the 3-dimensional array of FIG. 27 showing only the support structure, in accordance with some exemplary implementations.

FIG. 29 illustrates a partially levitating double magnetic element magneto-mechanical oscillator, in accordance with some exemplary implementations.

FIG. 30 illustrates a 3-dimensional array of partially levitating double magnetic element magneto-mechanical oscillators of FIG. 29, in accordance with some exemplary implementations.

FIG. 31 illustrates a partially levitating single magnetic element magneto-mechanical oscillator, in accordance with some exemplary implementations.

FIG. 32 illustrates a torsional magneto-mechanical chain oscillator, in accordance with some exemplary implementations.

FIG. 33 illustrates a torsional magneto-mechanical chain oscillator, in accordance with some other exemplary implementations.

FIG. 34 illustrates a 2-dimensional array of the torsional magneto-mechanical chain oscillators of FIG. 32.

FIG. 35 illustrates a 3-dimensional array of the torsional magneto-mechanical chain oscillators of FIG. 32.

FIG. 36 illustrates a torsional magneto-mechanical chain oscillator, in accordance with yet other implementations.

FIG. 37 illustrates a 3-dimensional array of the torsional magneto-mechanical chain oscillators of FIG. 35.

FIG. 38 schematically illustrates an example configuration of a power transmitter and a power receiver, in accordance with some exemplary implementations.

FIG. 39 is a flowchart of a method of transmitting power wirelessly, in accordance with some exemplary implementations.

FIG. 40 is a flowchart of a method of transmitting power wirelessly, in accordance with some other exemplary implementations.

FIG. 41 is a flowchart of a method of transmitting power wirelessly, in accordance with some other exemplary implementations.

FIG. 42 is a flowchart of a method for fabricating a plurality of magneto-mechanical oscillators, in accordance with some exemplary implementations.

FIG. 43 is a flowchart of a method for fabricating a plurality of magneto-mechanical oscillators, in accordance with some other exemplary implementations.

FIG. 44 is a flowchart of a method for fabricating a plurality of magneto-mechanical oscillators, in accordance with some other exemplary implementations.

The various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The detailed description set forth below in connection with the appended drawings is intended as a description of exemplary implementations of the invention and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations of the invention. In some instances, some devices are shown in block diagram form.

Wirelessly transferring power may refer to transferring any form of energy associated with electric fields, magnetic fields, electromagnetic fields, or otherwise from a transmitter to a receiver without the use of physical electrical conductors (e.g., power may be transferred through free space). The power output into a wireless field (e.g., a magnetic field) may be received, captured by, or coupled by a receiver to achieve power transfer.

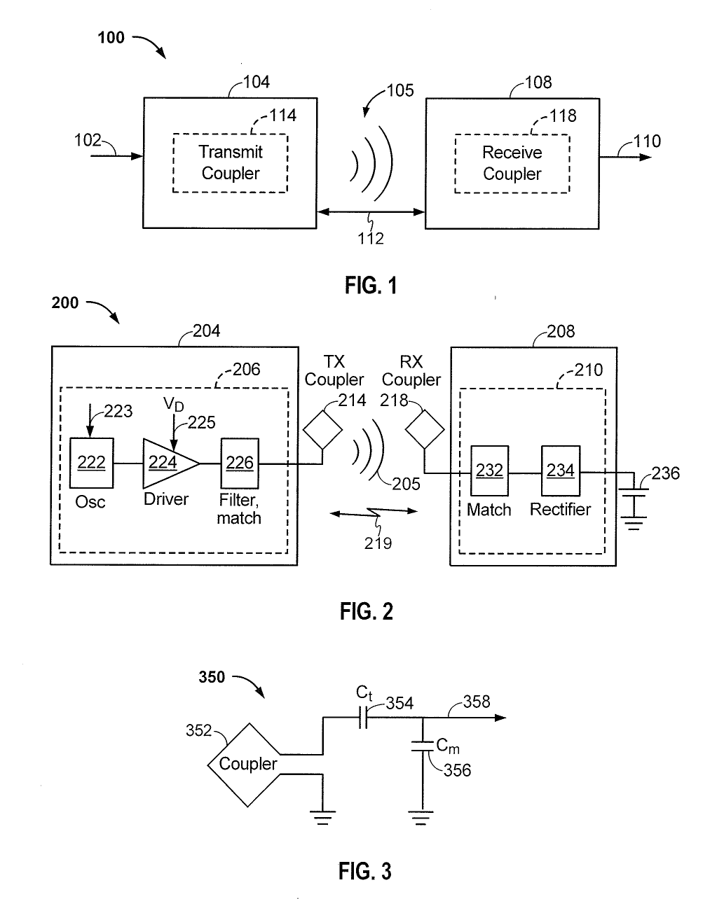

FIG. 1 is a functional block diagram of a wireless power transfer system 100, in accordance with some exemplary implementations. Input power 102 may be provided to a transmitter 104 from a power source (not shown) to generate a wireless (e.g., magnetic or electromagnetic) field 105 via a transmit coupler 114 for performing energy transfer. The receiver 108 may receive power when the receiver 108 is located in the wireless field 105 produced by the transmitter 104. The wireless field 105 corresponds to a region where energy output by the transmitter 104 may be captured by the receiver 108. A receiver 108 may couple to the wireless field 105 and generate output power 110 for storing or consumption by a device (not shown in this figure) coupled to the output power 110. Both the transmitter 104 and the receiver 108 are separated by a distance 112.

In one example implementation, power is transferred inductively via a time-varying magnetic field generated by the transmit coupler 114. The transmitter 104 and the receiver 108 may further be configured according to a mutual resonant relationship. When the resonant frequency of the receiver 108 and the resonant frequency of the transmitter 104 are substantially the same or very close, transmission losses between the transmitter 104 and the receiver 108 are minimal. However, even when resonance between the transmitter 104 and receiver 108 are not matched, energy may be transferred, although the efficiency may be reduced. For example, the efficiency may be less when resonance is not matched. Transfer of energy occurs by coupling energy from the wireless field 105 of the transmit coupler 114 to the receive coupler 118, residing in the vicinity of the wireless field 105, rather than propagating the energy from the transmit coupler 114 into free space.

Resonant coupling techniques may thus allow for improved efficiency and power transfer over various distances and with a variety of magneto-mechanical oscillator coupler configurations.

The receiver 108 may receive power when the receiver 108 is located in the wireless field 105 produced by the transmitter 104. The wireless field 105 corresponds to a region where energy output by the transmitter 104 may be captured by the receiver 108. The wireless field 105 may correspond to the “near-field” of the transmitter 104 as will be further described below. The transmitter 104 may include a transmit coupler 114 for coupling energy to the receiver 108. The receiver 108 may include a receive coupler 118 for receiving or capturing energy transmitted from the transmitter 104. The near-field may correspond to a region in which there are strong reactive fields resulting from the magnetic and/or electromagnetic fields generated by the transmit coupler 114 that minimally radiate power away from the transmit coupler 114. The near-field may correspond to a region that is within about one wavelength (or a fraction thereof) of the fundamental frequency at which the transmit coupler 114 operates.

As described above, efficient energy transfer may occur by coupling a large portion of the energy in the wireless field 105 to the receive coupler 118 rather than propagating most of the energy in an electromagnetic wave to the far field. When positioned within the wireless field 105, a “coupling mode” may be developed between the transmit coupler 114 and the receive coupler 118. The area around the transmit coupler 114 and the receive coupler 118 where this coupling may occur is referred to herein as a coupling-mode region.

FIG. 2 is a functional block diagram of a wireless power transfer system 200, in accordance with some other exemplary implementations. The system 200 may be a wireless power transfer system of similar operation and functionality as the system 100 of FIG. 1. However, the system 200 provides additional details regarding the components of the wireless power transfer system 200 as compared to FIG. 1. The system 200 includes a transmitter 204 and a receiver 208. The transmitter 204 includes transmit circuitry 206 that includes an oscillator 222, a driver circuit 224, and a filter and matching circuit 226. The oscillator 222 may be configured to generate a signal at a desired frequency that may be adjusted in response to a frequency control signal 223. The oscillator 222 provides the oscillator signal to the driver circuit 224. The driver circuit 224 may be configured to drive the transmit coupler 214 at a resonant frequency of the transmit coupler 214 based on an input voltage signal (V_{D}) 225.

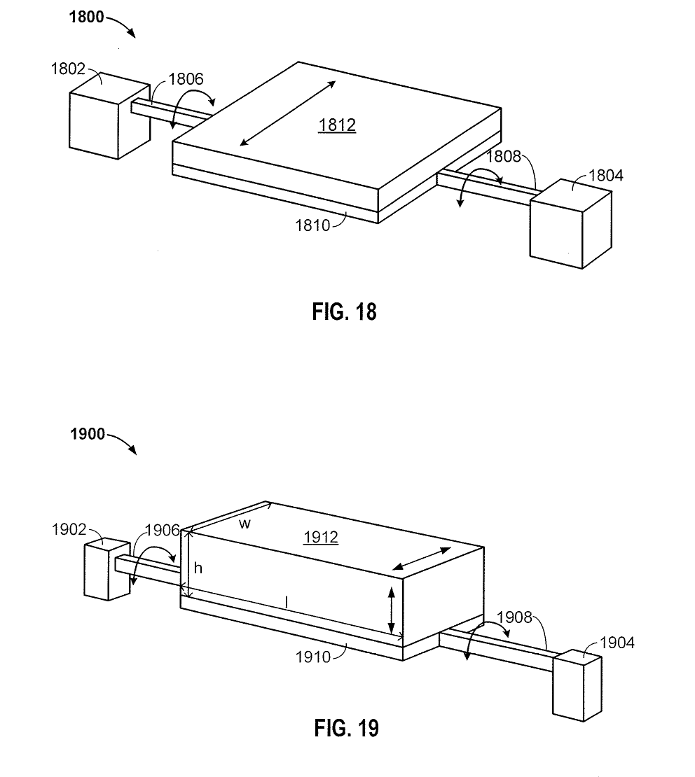

The filter and matching circuit 226 filters out harmonics or other unwanted frequencies and matches the impedance of the transmit circuitry 206 to the transmit coupler 214. As a result of driving the transmit coupler 214, the transmit coupler 214 generates a wireless field 205 to wirelessly output power at a level sufficient for charging a battery 236. As will be described in more detail in connection with FIGS. 18-37 below, the transmit coupler 214 may be configured to excite one or more (e.g., a 2-dimensional or 3-dimensional array of) magneto-mechanical oscillators (not shown in FIG. 2) to physically oscillate about at least one rotation axis in resonance with the wireless field 205. The physical resonant oscillation of the oscillators may reinforce the wireless field 205, increasing its strength.

The receiver 208 comprises receive circuitry 210 that includes a matching circuit 232 and a rectifier circuit 234. The matching circuit 232 may match the impedance of the receive circuitry 210 to the impedance of the receive coupler 218. The rectifier circuit 234 may generate a direct current (DC) power output from an alternate current (AC) power input to charge the battery 236. The receiver 208 and the transmitter 204 may additionally communicate on a separate communication channel 219 (e.g., Bluetooth, Zigbee, cellular, etc.). The receiver 208 and the transmitter 204 may alternatively communicate via in-band signaling using characteristics of the wireless field 205. In some implementations, the receiver 208 may be configured to determine whether an amount of power transmitted by the transmitter 204 and received by the receiver 208 is appropriate for charging the battery 236.

FIG. 3 is a schematic diagram of a portion of the transmit circuitry 206 or the receive circuitry 210 of FIG. 2. As illustrated in FIG. 3, transmit or receive circuitry 350 may include a coupler 352. The coupler 352 may also be referred to or be configured as a “conductor loop”, a coil, an inductor, or a “magnetic” coupler. The term “coupler” generally refers to a component that may wirelessly output or receive energy for coupling to another “coupler.”

The resonant frequency of the loop or magnetic couplers is based on the inductance and capacitance of the loop or magnetic coupler. Inductance may be simply the inductance created by the coupler 352, whereas, capacitance may be added via a capacitor (or the self-capacitance of the coupler 352) to create a resonant structure at a desired resonant frequency. As a non-limiting example, a capacitor 354 and a capacitor 356 may be added to the transmit or receive circuitry 350 to create a resonant circuit that selects a signal 358 at a resonant frequency. For larger sized couplers using large diameter couplers exhibiting larger inductance, the value of capacitance needed to produce resonance may be lower. Furthermore, as the size of the coupler increases, coupling efficiency may increase. This is mainly true if the size of both transmit and receive couplers increase. For transmit couplers, the signal 358, with a frequency that substantially corresponds to the resonant frequency of the coupler 352, may be an input to the coupler 352.

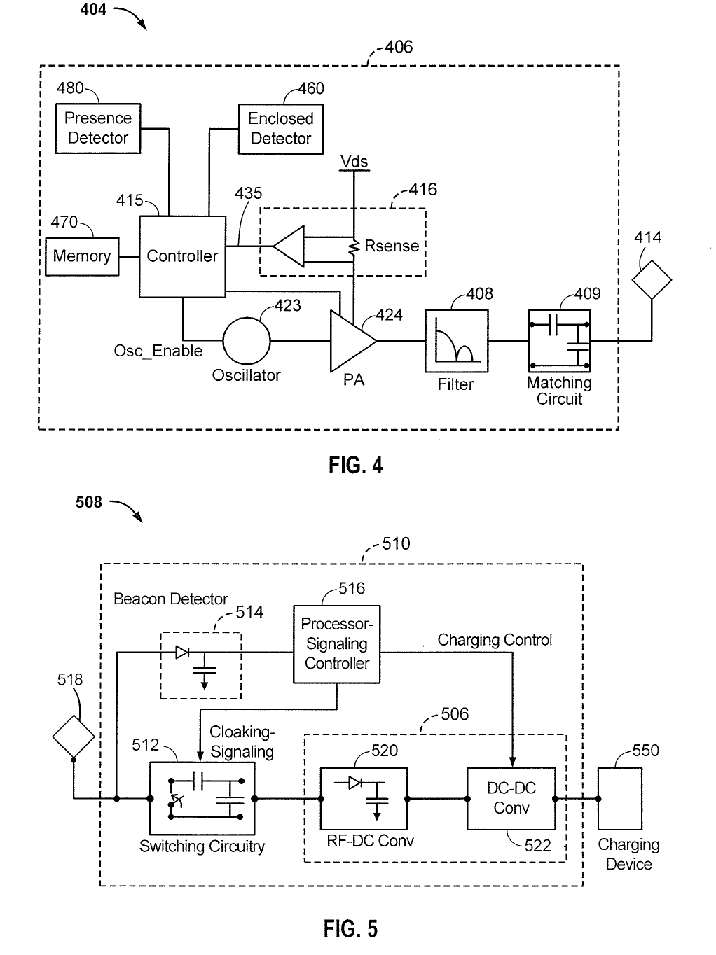

In order to ensure that the wireless power transmitters, such as the transmitter 204, operate within the specified parameters, testing equipment may subject the transmitter 204 (e.g., at the output of the filter and matching circuit 226) to a plurality of loading conditions having various load impedances. However, in practice, parasitic impedances (e.g., a parasitic capacitance) between electrical components in such testing equipment may prevent the testing equipment from accurately presenting very low impedances to the wireless power transmitter 204 under test. For example, in some cases tuning such testing equipment for a desired impedance of 1.2Ω, for example, may cause the testing equipment to provide an actual impedance of approximately 5Ω due to these parasitic impedances. These parasitic impedances may cause a positive shift in parasitic real resistance as the parasitic reactance increases. Accordingly, the present application contemplates offsetting the parasitic impedances (e.g., the real resistances and/or the imaginary reactances) presented by the testing equipment components to substantially reduce or eliminate the effect of those parasitic impedances on the wireless power transmitter 204 under test. Example implementations may be described in more detail in connection with FIGS. 4 and 5 below.

FIG. 4 is a functional block diagram of a transmitter 404 that may be used in the wireless power transfer system of FIG. 1, in accordance with some exemplary implementations of the invention. The transmitter 404 may include transmit circuitry 406 and a transmit coupler 414. The transmit coupler 414 may be the coupler 352 as shown in FIG. 3. Transmit circuitry 406 may provide radio frequency (RF) power to the transmit coupler 414 by providing an oscillating signal resulting in generation of energy (e.g., magnetic flux) about the transmit coupler 414. Transmitter 404 may operate at any suitable frequency.

Transmit circuitry 406 may include a fixed impedance matching circuit 409 for matching the impedance of the transmit circuitry 406 (e.g., 50 ohms) to the transmit coupler 414 and a low pass filter (LPF) 408 configured to reduce harmonic emissions to levels to prevent self-jamming of devices coupled to a receiver 108 (FIG. 1). Other exemplary implementations may include different filter topologies, including but not limited to, notch filters that attenuate specific frequencies while passing others and may include an adaptive impedance match, that may be varied based on measurable transmit metrics, such as output power to the coupler 414 or DC current drawn by the driver circuit 424. Transmit circuitry 406 further includes a driver circuit 424 configured to drive an RF signal as determined by an oscillator 423. The transmit circuitry 406 may be comprised of discrete devices or circuits, or alternately, may be comprised of an integrated assembly. An exemplary RF power output from the transmit coupler 414 may be on the order of 2.5 Watts.

Transmit circuitry 406 may further include a controller 415 for selectively enabling the oscillator 423 during transmit phases (or duty cycles) for specific receivers, for adjusting the frequency or phase of the oscillator 423, and for adjusting the output power level for implementing a communication protocol for interacting with neighboring devices through their attached receivers. It is noted that the controller 415 may also be referred to herein as a processor. Adjustment of oscillator phase and related circuitry in the transmission path may allow for reduction of out of band emissions, especially when transitioning from one frequency to another.

The transmit circuitry 406 may further include a load sensing circuit 416 for detecting the presence or absence of active receivers in the vicinity of the near-field generated by transmit coupler 414. By way of example, a load sensing circuit 416 monitors the current flowing to the driver circuit 424, that may be affected by the presence or absence of active receivers in the vicinity of the field generated by transmit coupler 414 as will be further described below. Detection of changes to the loading on the driver circuit 424 are monitored by controller 415 for use in determining whether to enable the oscillator 423 for transmitting energy and to communicate with an active receiver. As described more fully below, a current measured at the driver circuit 424 may be used to determine whether an invalid device is positioned within a wireless power transfer region of the transmitter 404.

The transmit coupler 414 may include a component including Litz wire or as an coupler strip with the thickness, width and metal type selected to keep resistive losses low. In a one implementation, the transmit coupler 414 may generally be configured for association with a larger structure such as a table, mat, lamp or other less portable configuration. A transmit coupler may also use a system of magneto-mechanical oscillators in accordance with some exemplary implementations described herein.

The transmitter 404 may gather and track information about the whereabouts and status of receiver devices that may be associated with the transmitter 404. Thus, the transmit circuitry 406 may include a presence detector 480, an enclosed detector 460, or a combination thereof, connected to the controller 415 (also referred to as a processor herein). The controller 415 may adjust an amount of power delivered by the driver circuit 424 in response to presence signals from the presence detector 480 and the enclosed detector 460. The transmitter 404 may receive power through a number of power sources, such as, for example, an AC-DC converter (not shown) to convert AC power present in a building, a DC-DC converter (not shown) to convert a DC power source to a voltage suitable for the transmitter 404, or directly from a DC power source (not shown).

As a non-limiting example, the presence detector 480 may be a motion detector utilized to sense the initial presence of a device to be charged that is inserted into the coverage area of the transmitter 404. After detection, the transmitter 404 may be turned on and the RF power received by the device may be used to toggle a switch on the Rx device in a pre-determined manner, which in turn results in changes to the driving point impedance of the transmitter 404.

As another non-limiting example, the presence detector 480 may be a detector capable of detecting a human, for example, by infrared detection, motion detection, or other suitable means. In some exemplary implementations, there may be regulations limiting the amount of power that a transmit coupler 414 may transmit at a specific frequency. In some cases, these regulations are meant to protect humans from electromagnetic radiation. However, there may be environments where a transmit coupler 414 is placed in areas not occupied by humans, or occupied infrequently by humans, such as, for example, garages, factory floors, shops, and the like. If these environments are free from humans, it may be permissible to increase the power output of the transmit coupler 414 above the normal power restrictions regulations. In other words, the controller 415 may adjust the power output of the transmit coupler 414 to a regulatory level or lower in response to human presence and adjust the power output of the transmit coupler 414 to a level above the regulatory level when a human is outside a regulatory distance from the electromagnetic field of the transmit coupler 414.

As a non-limiting example, the enclosed detector 460 (may also be referred to herein as an enclosed compartment detector or an enclosed space detector) may be a device such as a sense switch for determining when an enclosure is in a closed or open state. When a transmitter is in an enclosure that is in an enclosed state, a power level of the transmitter may be increased.

In exemplary implementations, a method by which the transmitter 404 does not remain on indefinitely may be used. In this case, the transmitter 404 may be programmed to shut off after a user-determined amount of time. This feature prevents the transmitter 404, notably the driver circuit 424, from running long after the wireless devices in its perimeter are fully charged. This event may be due to the failure of the circuit to detect the signal sent from either the repeater or the receive coupler 218 that a device is fully charged. To prevent the transmitter 404 from automatically shutting down if another device is placed in its perimeter, the transmitter 404 automatic shut off feature may be activated only after a set period of lack of motion detected in its perimeter. The user may be able to determine the inactivity time interval, and change it as desired. As a non-limiting example, the time interval may be longer than that needed to fully charge a specific type of wireless device under the assumption of the device being initially fully discharged.

FIG. 5 is a functional block diagram of a receiver 508 that may be used in the wireless power transfer system of FIG. 1, in accordance with some exemplary implementations of the invention. The receiver 508 includes receive circuitry 510 that may include a receive coupler 518. Receiver 508 further couples to device 550 for providing received power thereto. It should be noted that receiver 508 is illustrated as being external to device 550 but may be integrated into device 550. Energy may be propagated wirelessly to receive coupler 518 and then coupled through the rest of the receive circuitry 510 to device 550. By way of example, the charging device may include devices such as mobile phones, vehicles, portable music players, laptop computers, tablet computers, computer peripheral devices, communication devices (e.g., Bluetooth devices), digital cameras, hearing aids (and other medical devices), and the like.

Receive coupler 518 may be tuned to resonate at the same frequency, or within a specified range of frequencies, as transmit coupler 414 (FIG. 4). Receive coupler 518 may be similarly dimensioned with transmit coupler 414 or may be differently sized based upon the dimensions of the associated device 550. By way of example, device 550 may be a portable electronic device having diametric or length dimension smaller than the diameter or length of transmit coupler 414.

Receive circuitry 510 may provide an impedance match to the receive coupler 518. Receive circuitry 510 includes power conversion circuitry 506 for converting a received RF energy source into charging power for use by the device 550. Power conversion circuitry 506 includes an RF-to-DC converter 520 and may also include a DC-to-DC converter 522. RF-to-DC converter 520 rectifies the RF energy signal received at receive coupler 518 into a non-alternating power with an output voltage represented by V_{rect}. The DC-to-DC converter 522 (or other power regulator) converts the rectified RF energy signal into an energy potential (e.g., voltage) that is compatible with device 550 with an output voltage and output current. Various RF-to-DC converters are contemplated, including partial and full rectifiers, regulators, bridges, doublers, as well as linear and switching converters.

Receive circuitry 510 may further include switching circuitry 512 for connecting receive coupler 518 to the power conversion circuitry 506 or alternatively for disconnecting the power conversion circuitry 506. Disconnecting receive coupler 518 from power conversion circuitry 506 not only suspends charging of device 550, but also changes the “load” as “seen” by the transmitter 404 (FIG. 2).

As disclosed above, the transmitter 404 includes the load sensing circuit 416 that may detect fluctuations in the bias current provided to the driver circuit 424. Accordingly, transmitter 404 has a mechanism for determining when receivers are present in the transmitter's near-field.

When multiple receivers are present in a transmitter's near-field, it may be desirable to time-multiplex the loading and unloading of one or more receivers to enable other receivers to more efficiently couple to the transmitter. A receiver 508 may also be cloaked in order to eliminate coupling to other nearby receivers or to reduce loading on nearby transmitters. Furthermore, this switching between unloading and loading controlled by receiver 508 and detected by transmitter 404 may provide a communication mechanism from receiver 508 to transmitter 404 as is explained more fully below. Additionally, a protocol may be associated with the switching that enables the sending of a message from receiver 508 to transmitter 404.

In some exemplary implementations, communication between the transmitter 404 and the receiver 508 refers to a device sensing and charging control mechanism. In other words, the transmitter 404 may use on/off keying of the transmitted signal to adjust whether energy is available in the near-field. The receiver may interpret these changes in energy as a message from the transmitter 404. From the receiver side, the receiver 508 may use tuning and de-tuning of the receive coupler 518 to adjust how much power is being accepted from the field. In some cases, the tuning and de-tuning may be accomplished via the switching circuitry 512. The transmitter 404 may detect this difference in power used from the field and interpret these changes as a message from the receiver 508. It is noted that other forms of modulation of the transmit power and the load behavior may be utilized.

Receive circuitry 510 may further include signaling detector and beacon circuitry 514 used to identify received energy fluctuations that may correspond to informational signaling from the transmitter to the receiver. Furthermore, signaling and beacon circuitry 514 may also be used to detect the transmission of a reduced RF signal energy (i.e., a beacon signal) and to rectify the reduced RF signal energy into a nominal power for awakening either un-powered or power-depleted circuits within receive circuitry 510 in order to configure receive circuitry 510 for wireless charging.

Receive circuitry 510 further includes processor 516 for coordinating the processes of receiver 508 described herein including the control of switching circuitry 512 described herein. Processor 516 may monitor beacon circuitry 514 to determine a beacon state and extract messages sent from the transmitter 404. Processor 516 may also adjust the DC-to-DC converter 522 for improved performance.

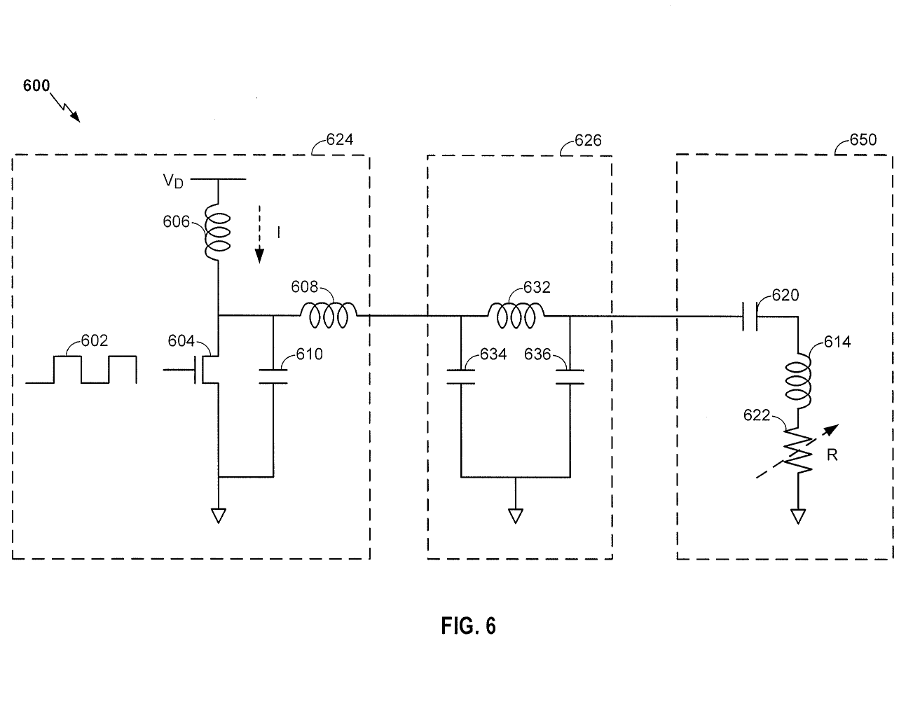

FIG. 6 is a schematic diagram of a portion of transmit circuitry 600 that may be used in the transmitter 404 of FIG. 4. The transmit circuitry 600 may include a driver circuit 624 as described above in FIG. 4. The driver circuit 624 may be a switching amplifier that may be configured to receive a square wave and output a sine wave to be provided to the transmit circuit 650. In some cases the driver circuit 624 may be referred to as an amplifier circuit. The driver circuit 624 may be driven by an input signal 602 from an oscillator 423 as shown in FIG. 4. The driver circuit 624 may also be provided with a drive voltage V_{D} that is configured to control the maximum power that may be delivered through a transmit circuit 650. To eliminate or reduce harmonics, the transmit circuitry 600 may include a filter circuit 626. The filter circuit 626 may be a three pole (capacitor 634, inductor 632, and capacitor 636) low pass filter circuit 626.

The signal output by the filter circuit 626 may be provided to a transmit circuit 650 comprising an coupler 614. The transmit circuit 650 may include a series resonant circuit that may resonate at a frequency of the filtered signal provided by the driver circuit 624. The load of the transmit circuit 650 may be represented by the variable resistor 622. The load may be a function of a receiver 508 that is positioned to receive power from the transmit circuit 650.

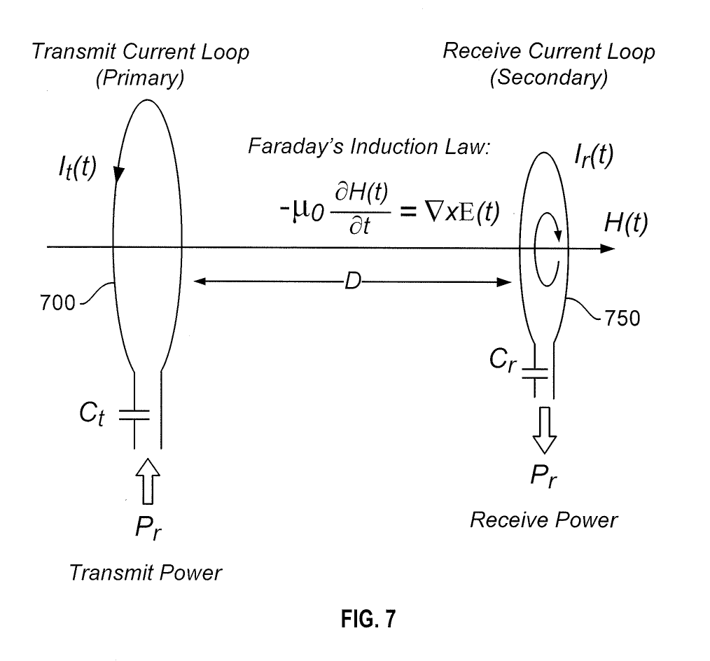

FIG. 7 illustrates non-radiative energy transfer that is based on Faraday's induction law, which may be expressed as:

$$- {μ}_{0} \frac{\partial H ( t )}{\partial t} = ∇ \times E ( t )$$

where ∇×E(t) denotes curl of the electric field generated by the alternating magnetic field. A transmitter forms a primary coupler (e.g., a transmit coupler as described above) and a receiver forms a secondary coupler (e.g., a receiver coupler as described above) separated by a transmission distance. The primary coupler represents the transmit coupler generating an alternating magnetic field. The secondary coupler represents the receive coupler that extracts electrical power from the alternating magnetic field using Faraday's induction law.

The generally weak coupling that exists between the primary coupler and secondary coupler may be considered as a stray inductance. This stray inductance, in turn, increases the reactance, which itself may hamper the energy transfer between primary coupler and secondary coupler. The transfer efficiency of this kind of weakly coupled system may be improved by using capacitors that are tuned to the precise opposite of the reactance at the operating frequency. When a system is tuned in this way, it becomes a compensated transformer which is resonant at its operating frequency. The power transfer efficiency is then only limited by losses in the primary coupler and secondary coupler. These losses are themselves defined by their quality or Q factors and the coupling factor between the primary coupler and the secondary coupler. Different tuning approaches may be used. Examples include, but are not limited to, compensation of the full reactance as seen at the primary coupler or secondary coupler (e.g., when either is open-circuited), and compensation of stray inductance. Compensation may also be considered as part of the source and load impedance matching in order to maximize the power transfer. Impedance matching in this way can hence increase the amount of power transfer.

As the distance D between the transmitter 700 and the receiver 750 increases, the efficiency of the transmission can decrease. At increased distances, larger loops, and/or larger Q factors may be used to improve the efficiency. However, when these devices are incorporated into a portable device, the size of the loop, thus its coupling and its Q-factor, may be limited by the parameters of the portable device.

Efficiency may be improved by reducing coupler losses. In general, losses may be attributed to imperfectly conducting materials, and eddy currents in the proximity of the loop. At lower frequencies (e.g., such as less than 1 MHz), flux magnification materials such as ferrite materials may be used to artificially increase the size of the coupler. Eddy current losses may inherently be reduced by concentrating the magnetic field. Special kinds of wire can also be used to lower the resistance, such as stranded or Litz wire at low frequencies to mitigate skin effect.

A type of resonant inductive energy transfer uses a magneto-mechanical system as described herein. The magneto-mechanical system may be part of an energy receiving system that picks up energy from an alternating magnetic field, converts it to mechanical energy, and then reconverts that mechanical energy into electrical energy using Faraday's induction law.

According to an implementation, the magneto-mechanical system is formed of a magnetic element, e.g. a permanent magnetic element, which is mounted in a way that allows it to oscillate under the force of an external alternating magnetic field. This transforms energy from the magnetic field into mechanical energy. In an implementation, this oscillation uses rotational moment around an axis perpendicular to the vector of the magnetic dipole moment m, and is also positioned in the center of gravity of the magnetic element. This allows equilibrium and thus minimizes the effect of the gravitational force. A magnetic field applied to this system produces a torque of T=μ₀(m×H). This torque tends to align the magnetic dipole moment of the elementary magnetic element along the direction of the field vector. Assuming an alternating magnetic field, the torque accelerates the moving magnet(s), thereby transforming the oscillating magnetic energy into mechanical energy.

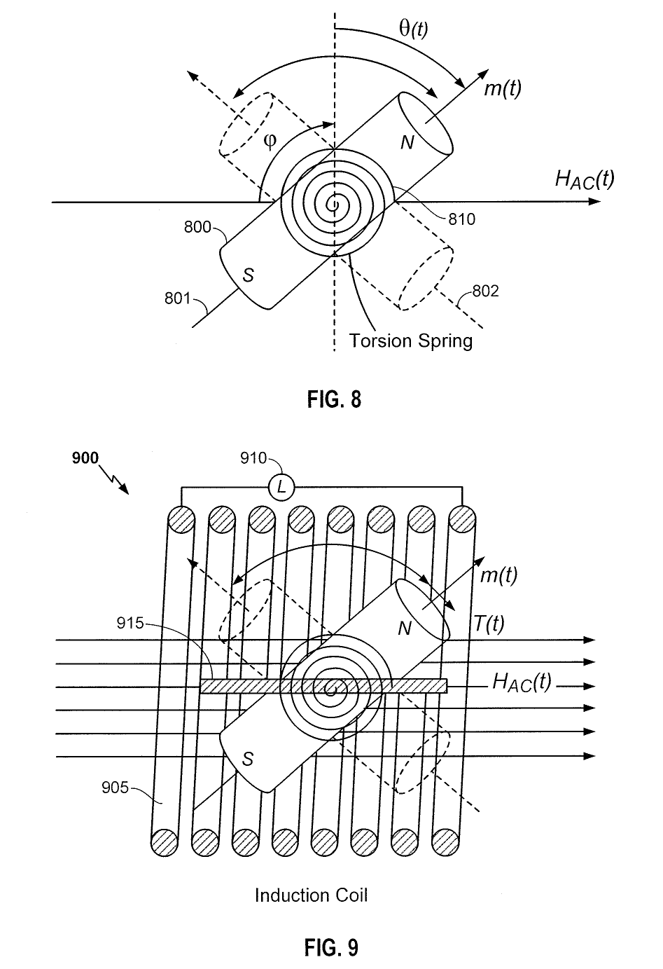

For example, in some implementations, a transmit coupler, e.g., as shown in any of FIGS. 1-4 and 7, may be utilized to generate a time-varying exciting magnetic field that may cause one or more first magneto-mechanical oscillators, as will be described below, to physically oscillate. Such physical oscillation of magnetic elements within the first oscillators may cause the first oscillators themselves to further generate a time-varying excited magnetic field at substantially the same frequency as the exciting magnetic field. In some implementations, this excited magnetic field may cause one or more second magneto-mechanical oscillators at a distance from the first oscillators to physically oscillate at the frequency of the excited magnetic field generated by the first oscillators, which in turn, causes magnetic elements within the second oscillators to generate an excited magnetic field at that frequency. A receive coupler, e.g., as shown in any of FIGS. 1-3, 5 and 7, located near or around the second oscillators may generate an alternating current under the influence of the excited magnetic field generated by the second oscillators. The operation of such systems will be described in more detail in connection with FIGS. 8-44 below.

FIG. 8 schematically illustrates an example magneto-mechanical oscillator, in accordance with some exemplary implementations. The magneto-mechanical oscillator of FIG. 8 comprises a magnetic element 800 having a magnetic moment m(t) (e.g., a vector having a constant magnitude but an angle that is time-varying, such as a magnetic dipole moment) and the magnetic element 800 is mechanically coupled to an underlying substrate (not shown) by at least one spring (e.g., a torsion spring 810). This spring holds the magnetic element in position shown as 801 when no torque from the magnetic field is applied. This no-torque position 801 is considered 0. Magnetic torque causes the magnetic element 800 to move against the restoring force of the torsion spring 810, to the position 802, against the force of the spring with spring constant K_{R}. The magneto-mechanical oscillator may be considered a torsion pendulum with an inertial moment I and exhibiting a resonance at a frequency proportional to K_{R} and I. Frictional losses and in most cases a very weak electromagnetic radiation is caused by the oscillating magnetic moment. If this magneto-mechanical oscillator is subjected to an alternating field H_{AC}(t) with a frequency near the resonance frequency of the magneto-mechanical oscillator, then the magneto-mechanical oscillator will oscillate with an angular displacement θ(t) depending on the intensity of the applied magnetic field and reaching a maximum, peak displacement at resonance.

According to another implementation, some or all of the restoring force of the spring may be replaced by an additional static magnetic field H₀. This static magnetic field may be oriented to provide the torque T₀=μ₀(m×H₀). Another implementation may use both the spring and a static magnetic field to produce the restoring force of the magneto-mechanical oscillator. The mechanical energy is reconverted into electrical energy using Faraday induction, e.g. the dynamo principle. This may be used for example an induction coil 905 wound around the magneto-electrical system 900 as shown in FIG. 9. In another example, the mechanical energy is reconverted into electrical energy using another type of circuit configured to directly convert the mechanical motion into electrical power or otherwise couple energy from the magnetic field generated by the moving magnets. A load such as 910 may be connected across the coil 905. This load appears as a mechanical torque dampening the system and lowering the Q factor of the magneto-mechanical oscillator. In addition, when magnetic elements are oscillating and thus generating a strong alternating magnetic field component and if the magnetic elements are electrically conducting, eddy currents in the magnetic elements will occur. These eddy currents will also contribute to system losses.

In general, some eddy currents may be also produced by the alternating magnetic field that results from the current in the coupling coil. Smaller magnetic elements in the magneto-mechanical system may reduce eddy current effects. According to an implementation, an array of smaller magnetic elements is used in order to minimize this loss effect.

A magneto-mechanical system will exhibit saturation if the angular displacement of the magnetic element reaches a peak value. This peak value may be determined from the direction and intensity of the external H field or by the presence of a displacement stopper such as 915 to protect the torsion spring against plastic deformation. This may also be limited by the packaging, such as the limited available space for a magnetic element to rotate within. Electric breaking by modifying the electric loading may be considered an alternative method to control saturation and thus prevent damaging the magneto-mechanical system.

According to one implementation and assuming a loosely coupled regime (e.g., weak coupling, such as in the case of energy harvesting from an external magnetic field generated by a large loop antenna surrounding a large space), optimum matching may be obtained when the loaded Q becomes half of the unloaded Q. According to an implementation, the induction coil is designed to fulfill that condition to maximize the amount of output power. If coupling between transmitter and receiver is stronger (e.g., a tightly coupled regime), optimum matching may utilize a loaded Q that is significantly smaller than the unloaded Q.

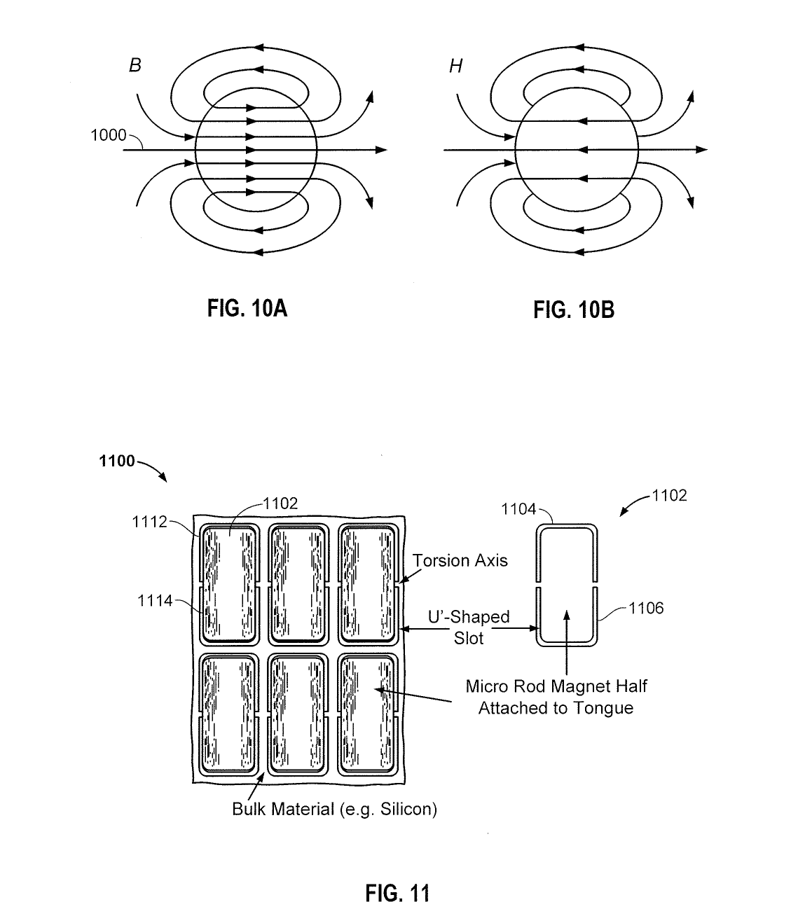

When using an array of such moving magnets, there may be mutual coupling between the magnetic elements forming the array. This mutual coupling can cause internal forces and demagnetization. According to an implementation, the array of magnetic elements may be radially symmetrical, e.g., spheroids, either regular or prolate, as shown in FIGS. 10A and 10B. FIG. 10A shows the parallel field lines of the magnetic flux density in a magnetized sphere. FIG. 10B shows the corresponding magnetic field strength (H) in a magnetized sphere. From these figures that may be seen that there may be virtually zero displacement forces between magnetic elements in a spheroid shaped three-dimensional array.

Therefore, the magnetic elements are preferably in-line with an axis 1000 of the spheroid or the disc. This causes the internal forces to vanish for angular displacement of the magnets. This causes the resonance frequency to be solely defined by the mechanical system parameters. A sphere has these advantageous factors, but may also have a demagnetization factor is low as ⅓, where an optimum demagnetization factor is one. Assuming equal orientation of axes in all directions, a disc shaped array can also be used. A disc-shaped 3D array may also result in low displacement forces, if the disc radius is much larger than its thickness and if the magnetic elements are appropriately oriented and suspended. Discs may have a higher magnetization factor, for example closer to 1.

Magnetization factor of a disc will depend on the width to diameter ratio. A disc-shaped array may be packaged into a form factor that is more suitable for integration into a device, since spheroids do not have a flat part that may be easily used without increasing the thickness of the host device.

Using an array of micro magneto-mechanical oscillators enables the design of a system with a performance that may be better than anything achievable in practice with a single macro oscillator. A macro sized oscillator would require an extremely high Q-factor that could not be realized in a mechanical system.

In addition, theoretical analysis of wireless energy transfer based on magneto-mechanical systems shows that within a first order approximation and in a weakly coupled regime, the energy transfer efficiency increases proportionally to the Q-factor and to the square of the magnetization, and is inversely proportional to the density of the inertial moment. In addition, the maximum transferable power, which is limited by saturation effects, increases proportionally to the frequency, to the square of the product of the magnetic moments, and to the peak angular displacement of the magnets.

Certain implementation use micro-electromechanical systems (MEMS) to create the magneto-mechanical systems, as will be described below. In such systems, it may be desirable to utilize magneto-mechanical metamaterials subject to one or more of the following requirements. The metamaterial should have a high total magnetic moment per volume (i.e., a high remanence of the permanent magnetic material, a high packing density described by the volume fraction of magnetic material or fill factor). Remanence may also be called “remanent magnetization” and is the magnetization left behind in a ferromagnetic material after an external magnetic field is removed. Elementary oscillators should have a small size (e.g., approximately 10 μm) in order to minimize a moment of inertia per volume. The metamaterial should have low losses (i.e., the elementary oscillators should have a high unloaded Q, e.g., 500+, depending upon the operating conditions of the system. The displacement angles of the elementary oscillator magnetic elements should be relatively large, e.g., preferably more than ±10° in either direction. The metamaterial should be designed to achieve a resonance frequency in the kHz to MHz range. The metamaterial should have sufficient mechanical stability to be durable and processable and should exhibit relatively low fatigue of mechanical elements to increase mean life time. The metamaterial should be manufacturable utilizing a cost effective process. However, some of these preferences may be contradictory. For example, a desired spring constant of the oscillators may be limited by the size of the oscillator and materials of its construction (e.g., soft springs cannot be made arbitrarily small and still retain functionality and suitable lifetimes). Also, greater displacement angles of the oscillators may adversely affect possible fill factors due to the greater range of motion and need for space to accommodate the same.

FIG. 11 schematically illustrates an example array of magneto-mechanical oscillators fabricated using MEMS technology, in accordance with some exemplary implementations. An array 1100 may be formed of a number of magnetic elements such as 1102. Each magnetic element 1102 is formed of two U-shaped slots 1112, 1114 that are micro-machined or etched into a silicon substrate. A permanent rod magnetic element 1104, 1106 of similar size is formed within the slots. The magnetic element may be 10 μm or smaller. At the micrometer level, crystalline materials may behave differently than larger sizes. Hence, this system can provide considerable angular displacement e.g. as high as 10° or more and extremely high Q factors. Other configurations, in accordance with some exemplary implementations can instead utilize other structures (e.g., torsional springs), in other positions and/or in other orientations, which couple the magneto-mechanical oscillators to the surrounding material.

These devices may be formed in a single bulk material such as silicon. FIG. 11 shows an example structure, in accordance with some exemplary implementations. In an example configuration, the magnetic elements 1102 shown in FIG. 11 may be fabricated in a two-dimensional structure in a common plane (e.g., a portion of a planar silicon wafer, shown in FIG. 11 in a top view, oriented parallel to the plane of the page) and such two-dimensional structures may be assembled together to form a three-dimensional structure. However, the example structure shown in FIG. 11 should not be interpreted as only being in a two-dimensional wafer structure. In other example configurations, different sub-sets of the magnetic elements 1102 may be fabricated in separate structures that are assembled together to form a three-dimensional structure (e.g., the three top magnetic elements 1102, shown in FIG. 11 in a side view, may be fabricated in a portion of one silicon wafer oriented perpendicularly to the plane of the page and the three bottom magnetic elements 1102, shown in FIG. 11 in a side view, may be fabricated in a portion of another silicon wafer oriented perpendicularly to the plane of the page).

The magnetic elements 1104, 1106 can have a high magnetization, e.g., higher than 1 Tesla. In some exemplary implementations, the magnetic element itself may be composed of two half pieces, one piece attached to the upper side and the other piece attached to the lower side. These devices may be mounted so that the center of gravity coincides with the rotational axes. The device may be covered with a low friction material, or may have a vacuum located in the area between the tongue and bulk material in order to reduce type the friction.

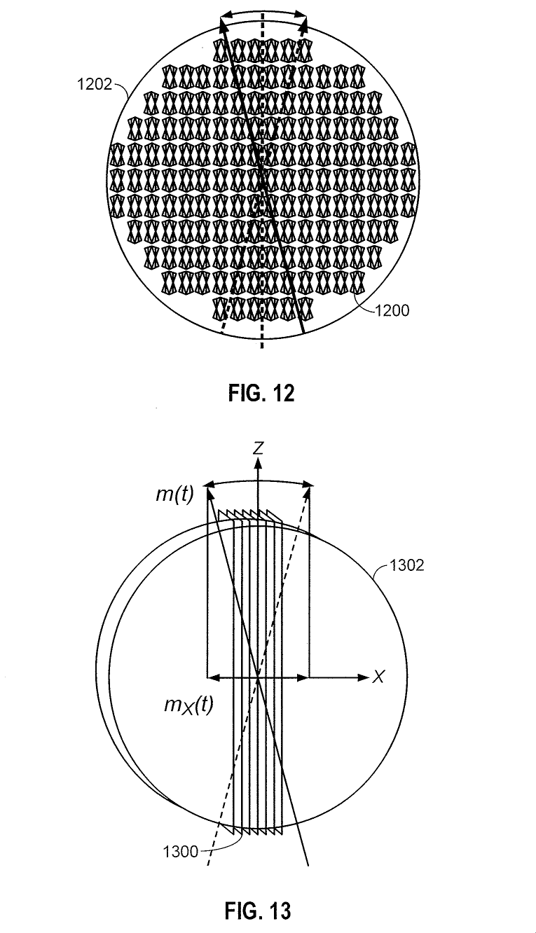

FIG. 12 schematically illustrates a cut through area of a three-dimensional array of magneto-mechanical oscillators 1200, in accordance with some exemplary implementations. While the example structure shown in FIG. 12 could be in a single two-dimensional wafer structure oriented parallel to the page, FIG. 12 should not be interpreted as only being in a two-dimensional wafer structure. For example, the three-dimensional array 1202 through which FIG. 12 shows a two-dimensional cut can comprise a plurality of planar wafer portions oriented perpendicularly to the page such that the cross-sectional view of FIG. 12 includes side views of magneto-mechanical oscillators 1200 from multiple such planar wafer portions. In one implementation, the array 1202 itself is formed of a radial symmetric shape, such as disc shaped. The disc shaped array 1202 of FIG. 12 may provide a virtually constant demagnetization factor at virtually all displacement angles. In this implementation, an induction coil may be wound around the disc to pick up the dynamic component of the oscillating induction field generated by the MEMS-magneto-mechanical system. The resulting dynamic component of the system may be expressed as

mₓ(t)=|m|·sin θ(t)·eₓ

FIG. 13 schematically illustrates an example induction coil 1300 wound around a disk 1302 having a plurality of magneto-mechanical oscillators, in accordance with some exemplary implementations.

The implementations described and particularly below may be incorporated into either transmitters or receiver devices. While the description below discloses various features of a power transmitter or a power receiver, many of these same concepts and structures of the power transmitter or receiver may be used in a power receiver or transmitter as well, in accordance with some exemplary implementations. Furthermore, a power transfer system comprising at least one power transmitter and at least one power receiver can have one or both of the at least one power transmitter and the at least one power receiver having a structure as described herein.

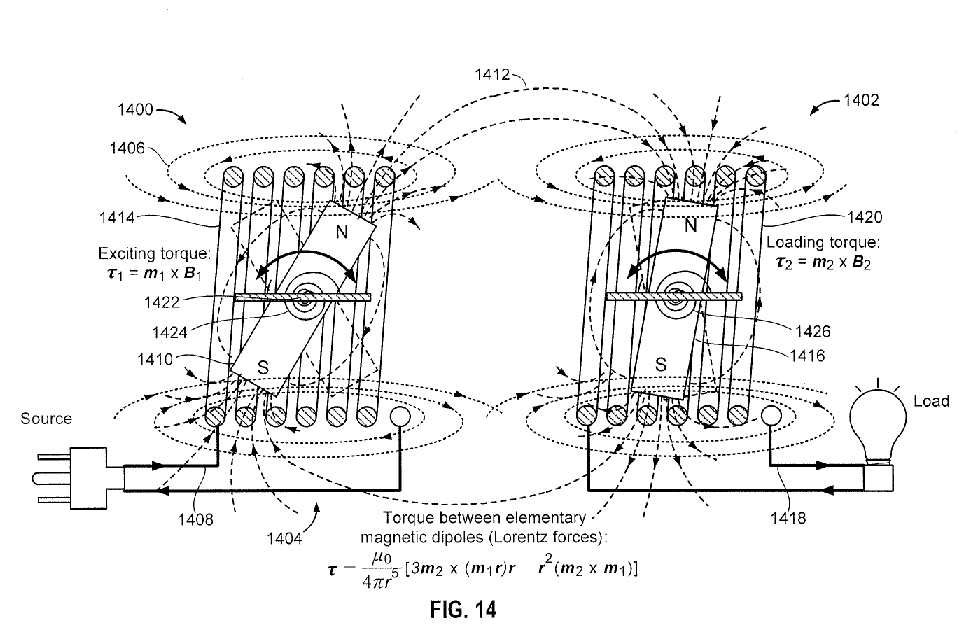

FIG. 14 schematically illustrates an example power transmitter 1400 configured to wirelessly transfer power to at least one power receiver 1402, in accordance with some exemplary implementations. The power transmitter 1400 comprises at least one excitation circuit 1404 configured to generate a time-varying (e.g., alternating) magnetic field 1406 in response to a time-varying (e.g., alternating) electric current 1408 flowing through the at least one excitation circuit 1404. The time-varying magnetic field 1406 has an excitation frequency. The power transmitter 1400 further comprises a plurality of magneto-mechanical oscillators 1410 (e.g., that are mechanically coupled to at least one substrate, which is not shown in FIG. 14). FIG. 14 schematically illustrates one example magneto-mechanical oscillator 1410 compatible with certain implementations described herein for simplicity, rather than showing the plurality of magneto-mechanical oscillators 1410. Each magneto-mechanical oscillator 1410 of the plurality of magneto-mechanical oscillators has a mechanical resonant frequency substantially equal to the excitation frequency. The plurality of magneto-mechanical oscillators 1410 is configured to generate a time-varying (e.g., alternating) magnetic field 1412 in response to movement of the plurality of magneto-mechanical oscillators 1410 under the influence of the first magnetic field 1406.

As schematically illustrated by FIG. 14, the at least one excitation circuit 1404 comprises at least one coil 1414 surrounding (e.g., encircling) at least a portion of the plurality of magneto-mechanical oscillators 1410. The at least one coil 1414 has a time-varying (e.g., alternating) current 1408 I₁(t) flowing through the at least one coil 1414, and generates a time-varying (e.g., alternating) first magnetic field 1406 which applies a torque (labeled as “exciting torque” in FIG. 14) to the magneto-mechanical oscillators 1410. Although the coil 1414 is shown, the present application is not so limited and other types of excitation circuits capable of generating a time varying magnetic field for inducing motion of the oscillators. In response to the first time-varying magnetic field 1406, the magneto-mechanical oscillators 1410 rotate about an axis. In this way, the at least one excitation circuit 1404 and the plurality of magneto-mechanical oscillators 1410 convert electrical energy into mechanical energy. The magneto-mechanical oscillators 1410 generate a second magnetic field 1412 which wirelessly transmits power to the power receiver 1402 (e.g., a power receiver as described above). For example, the power receiver 1402 can comprise a receiving plurality of magneto-mechanical oscillators 1416 configured to rotate in response to a torque applied by the second magnetic field 1412 and to induce a current 1418 in a pick-up coil 1420 (e.g., a power extraction circuit), thereby converting mechanical energy into electrical energy. Although the pick-up coil 1420 is shown, the present application is not so limited and any power extraction circuit configured to convert the mechanical energy into electrical energy for powering a load is also contemplated.

As schematically illustrated by FIG. 14 for a pick-up coil for a power transmitter utilizing a plurality of magneto-mechanical oscillators, the at least one coil 1414 of the power transmitter 1400 can comprise a single common coil that is wound around at least a portion of the plurality of magneto-mechanical oscillators 1410 of the power transmitter 1400. The wires of the at least one coil 1414 may be oriented substantially perpendicular to the “dynamic” component (described in more detail below) of the magnetic moment of the plurality of magneto-mechanical oscillators 1410 to advantageously improve (e.g., maximize) coupling between the at least one coil 1414 and the plurality of magneto-mechanical oscillators 1410. As described more fully below, the excitation current flowing through the at least one coil 1414 may be significantly lower than those used in other resonant induction systems. Thus, certain implementations described herein advantageously do not have special requirements for the design of the at least one coil 1414.

As described above with regard to FIG. 11 for the magneto-mechanical oscillators of a power receiver, the magneto-mechanical oscillators 1410 of the power transmitter 1400, in accordance with some exemplary implementations may be MEMS structures fabricated on at least one substrate (e.g., a semiconductor substrate, a silicon wafer) using lithographic processes such as are known from MEMS fabrication techniques. Each magneto-mechanical oscillator 1410 of the plurality of magneto-mechanical oscillators 1410 can comprise a movable magnetic element configured to rotate about an axis 1422 in response to a torque applied to the movable magnetic element by the first magnetic field 1406. The movable magnetic element may comprise at least one spring 1424 (e.g., torsion spring, compression spring, extension spring) mechanically coupled to the substrate and configured to apply a restoring force to the movable magnetic element in response to rotation of the movable magnetic element. The magneto-mechanical oscillators 1416 of the power receiver 1402 can comprise a movable magnetic element (e.g., magnetic dipole) comprising at least one spring 1426 (e.g., torsion spring, compression spring, extension spring) mechanically coupled to a substrate of the power receiver 1402 and configured to apply a restoring force to the movable magnetic element in response to rotation of the movable magnetic element.

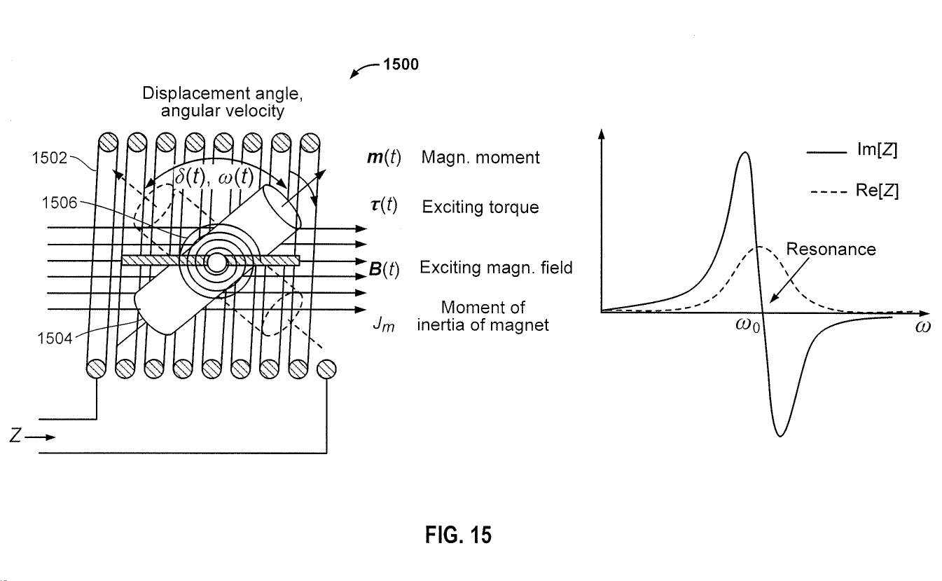

FIG. 15 schematically illustrates an example power transmitter 1500, in accordance with some exemplary implementations in which the at least one excitation circuit 1502 is driven at a frequency substantially equal to a mechanical resonant frequency of the magneto-mechanical oscillators 1504. The at least one excitation circuit 1502 generates the first magnetic field which applies the exciting torque to the magneto-mechanical oscillator 1504, which has a magnetic moment and a moment of inertia. The direction of the magnetic moment is time-varying, but its magnitude is constant. The resonant frequency of a magneto-mechanical oscillator 1504 is determined by the mechanical properties of the magneto-mechanical oscillator 1504, including its moment of inertia (a function of its size and dimensions) and spring constants.

The input impedance of the at least one excitation circuit 1502 has a real component and an imaginary component, both of which vary as a function of frequency. Near the resonant frequency of the magneto-mechanical oscillators 1504, the real component is at a maximum, and the imaginary component disappears (e.g., is substantially equal to zero) (e.g., the current and voltage of the at least one excitation circuit 1502 are in phase with one another). At this frequency, the impedance, as seen at the terminals of the at least one coil, appears as purely resistive, even though a strong alternating magnetic field may be generated by the magneto-mechanical oscillators. The combination of the at least one excitation circuit 1502 and the plurality of magneto-mechanical oscillators 1504 can appear as an “inductance-less inductor” which advantageously avoids (e.g., eliminates) the need for resonance-tuning capacitors as are used in other power transmitters.

Since the time-varying (e.g., alternating) second magnetic field is generated by the plurality of magneto-mechanical oscillators 1504, there are no high currents flowing through the electrical conductors of the at least one excitation circuit 1502 at resonance, such as exist in other resonant induction systems. Therefore, losses in the at least one excitation circuit 1502 (e.g., the exciter coil) may be negligible. In certain such configurations, thin wire or standard wire may be used in the at least one excitation circuit 1502, rather than Litz wire. The main losses occur in the plurality of magneto-mechanical oscillators 1504 and its surroundings due to mechanical friction, air resistance, eddy currents, and radiation in general. The magneto-mechanical oscillators 1504 can have Q-factors which largely exceed those of electrical resonators, particularly in the kHz and MHz ranges of frequencies. For example, the Q-factor of the plurality of magneto-mechanical oscillators 1504 (either in use for a transmitter system or a receiver system) may be greater than 500, or even greater than 10,000. Such high Q-factors may be more difficult to achieve in other resonant induction systems using capacitively loaded wire loops in some cases.

The large Q-factor of certain implementations described herein can also be provided by the plurality of magneto-mechanical oscillators 1504. The power that may be wirelessly transmitted to a load is the product of the root-mean-square (RMS) values of the torque τ_{RMS} applied to the magneto-mechanical oscillator 1504 and the frequency (e.g., angular velocity) ω_{RMS}. To allow for sufficient oscillation (e.g., sufficient angular displacement of the magneto-mechanical oscillator 1504) when power transfer distances increase, the torque τ_{RMS} (e.g., the dampening torque applied to the magneto-mechanical oscillator 1504 of a power transmitter 1500, or the loading torque applied to the magneto-mechanical oscillator of a power receiver) may be reduced, but such increased distances result in lower power. This power loss may be compensated for by increasing the frequency ω_{RMS}, within the limits given by the moment of inertia of the magneto-mechanical oscillators 1504 and the torsion springs 1506. The performance of the magneto-mechanical oscillator 1504 may be expressed as a function of the gyromagnetic ratio γ=m/Jₘ (where m is the magnetic moment of the magneto-mechanical oscillator 1504, and Jₘ is the moment of inertia of the magneto-mechanical oscillator 1504), and this ratio can advantageously be configured to be sufficiently high to produce sufficient performance at higher frequencies.

A plurality of small, individually oscillating magneto-mechanical oscillators arranged in a regular three-dimensional array can advantageously be used in a transmitter or receiver, instead of a single permanent magnetic element. The plurality of magneto-mechanical oscillators can have a larger gyromagnetic ratio than a single permanent magnetic element having the same total volume and mass as the plurality of magneto-mechanical oscillators. The gyromagnetic ratio of a three-dimensional array of N magneto-mechanical oscillators with a sum magnetic moment m and a sum mass Mₘ may be expressed as:

$$γ ( N ) = \frac{12 \cdot N \cdot \frac{m}{N}}{\frac{{NM}_{m}}{N} {( \frac{{l}_{m}}{\sqrt[3]{N}} )}^{2}} = \frac{12 m}{{M}_{m} {l}_{m}^{2}} {\sqrt[3]{N}}^{2}$$

where lₘ denotes the length of an equivalent single magnetic element (N=1).

This equation shows that the gyromagnetic ratio increases to the power of ⅔ with decreasing size of the magneto-mechanical oscillators. In other words, a large magnetic moment produced by an array of small magneto-mechanical oscillators may be accelerated and set into oscillation by a faint torque (e.g., the exciting torque produced by a small excitation current flowing through the at least one excitation current of a power transmitter or the loading torque in a power receiver produced by a distant power transmitter). The performance of the plurality of magneto-mechanical oscillators may be increased by increasing the number of magneto-mechanical oscillators since the magnetic moment increases more than does the moment of inertia by increasing the number of magneto-mechanical oscillators. Using an array of magneto-mechanical oscillators (e.g., with features size in the micron range), resonant frequencies far into the MHz range may be used.

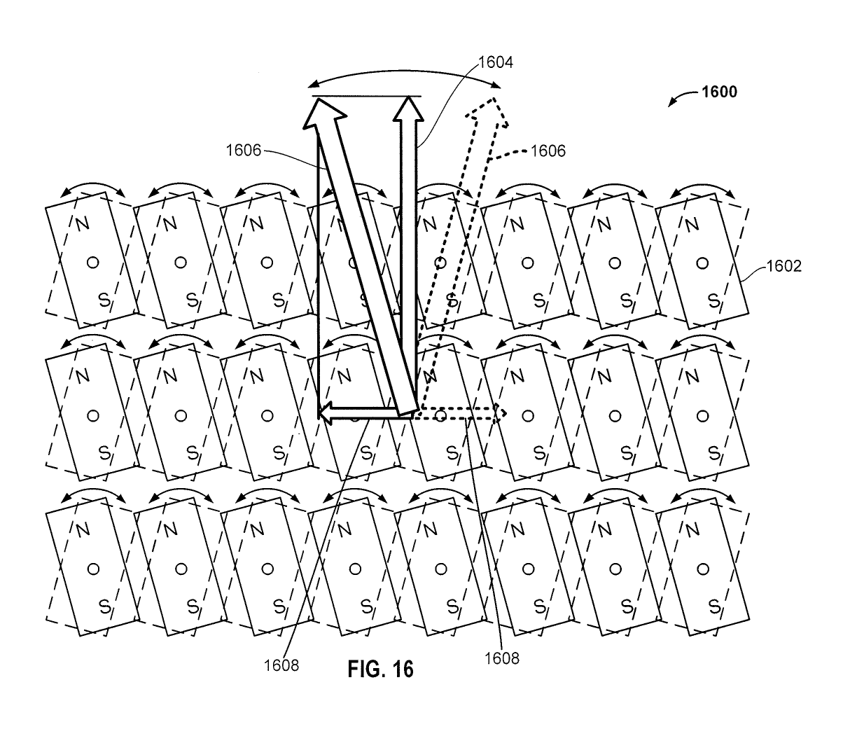

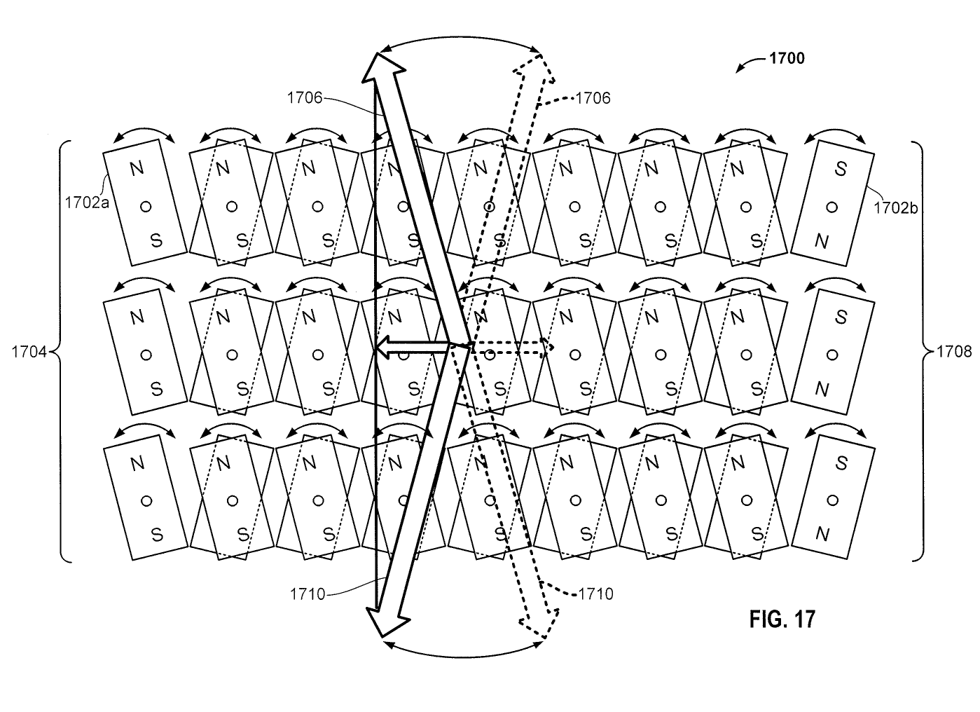

FIG. 16 schematically illustrates an example portion 1600 of a configuration of a plurality of magneto-mechanical oscillators 1602, in accordance with some exemplary implementations. The portion 1600 shown in FIG. 16 comprises a set of magneto-mechanical oscillators 1602. This arrangement of magneto-mechanical oscillators 1602 in a regular structure is similar to that of a plane in an atomic lattice structure (e.g., a three-dimensional crystal).

The oscillation of the magneto-mechanical oscillators 1602 between the solid positions and the dashed positions produces a sum magnetic moment that may be decomposed into a “quasi-static” component 1604 (denoted in FIG. 16 by the vertical solid arrow) and a “dynamic” component 1606 (denoted in FIG. 16 by the solid and dashed arrows at an angle to the vertical, and having a horizontal component 1608 shown by solid and dashed arrows). The dynamic component 1606 is responsible for energy transfer. For an example configuration such as shown in FIG. 16, for a maximum angular displacement of 30 degrees, a volume utilization factor of 20% for the set of magneto-mechanical oscillators 1602, a rare-earth metal magnetic material having 1.6 Tesla at its surface, a “dynamic” flux density in the order of 160 milli-Tesla peak may be achieved virtually without hysteresis losses, thereby outperforming certain other ferrite technologies.

However, the quasi-static component 1604 may be of no value in the energy transfer. In fact, in practical applications, it may be desirable to avoid (e.g., lessen or eliminate) the quasi-static component 1604, since it results in a strong magnetization (e.g., such as that of a strong permanent magnet) that can attract any magnetic materials in the vicinity of the structure towards the plurality of magneto-mechanical oscillators 1602.

The sum magnetic field generated by the plurality of magneto-mechanical oscillators 1602 can cause the individual magneto-mechanical oscillators 1602 to experience a torque such that they rest at a non-zero displacement angle. These forces may also change the effective torsion spring constant, thus modifying the resonant frequency. These forces may be controlled (e.g., avoided, reduced, or eliminated) by selecting the macroscopic shape of the array of the plurality of magneto-mechanical oscillators 1602 to be rotationally symmetric (e.g., a disk-shaped array). For example, using an array that is radially symmetrical (e.g., spheroidal, either regular or prolate, as shown in FIGS. 10A, 10B, and 12) can produce effectively zero displacement between the magneto-mechanical oscillators 1602 in a spheroid-shaped three-dimensional array. The field lines of some magnetic field components inside a magnetized disk are parallel for any orientation of the magnetic moment, and in a disk-shaped array, resonant frequencies may be determined mainly by the moment of inertia and the torsional spring constant of the magneto-mechanical oscillators.

FIG. 17 schematically illustrates an example configuration in which the plurality of magneto-mechanical oscillators 1702 is arranged in a three-dimensional array 1700 in which the quasi-static components of various portions of the plurality of magneto-mechanical oscillators 1702 cancel one another, in accordance with some exemplary implementations. The three-dimensional array 1700 of FIG. 17 comprises at least one first plane 1704 (e.g., a first layer) comprising a first set of magneto-mechanical oscillators 1702a of the plurality of magneto-mechanical oscillators 1702, with each magneto-mechanical oscillator 1702a of the first set of magneto-mechanical oscillators 1702a having a magnetic moment pointing in a first direction. The first set of magneto-mechanical oscillators 1702a has a first summed magnetic moment 1706 (denoted in FIG. 17 by the top solid and dashed arrows) comprising a time-varying component and a time-invariant component. The three-dimensional array 1700 further comprises at least one second plane 1708 (e.g., a second layer) comprising a second set of magneto-mechanical oscillators 1702b of the plurality of magneto-mechanical oscillators 1702. Each magneto-mechanical oscillator 1702b of the second set of magneto-mechanical oscillators 1702b has a magnetic moment pointing in a second direction. The second set of magneto-mechanical oscillators 1702b has a second summed magnetic moment 1710 (denoted in FIG. 17 by the bottom solid and dashed arrows) comprising a time-varying component and a time-invariant component. The time-invariant component of the first summed magnetic moment 1706 and the time-invariant component of the second summed magnetic moment 1710 have substantially equal magnitudes as one another and point in substantially opposite directions as one another. In this way, the quasi-static components of the magnetic moments of the first set of magneto-mechanical oscillators 1702a and the second set of magneto-mechanical oscillators 1702b cancel one another out (e.g., by having the polarities of the magneto-mechanical oscillators alternate between adjacent planes of a three-dimensional array 1700). In contrast, the time-varying components of the first summed magnetic moment 1706 and the second summed magnetic moment 1710 have substantially equal magnitudes as one another and point in substantially the same direction as one another.

The structure of FIG. 17 is analogous to the structure of paramagnetic materials that have magnetic properties (e.g., a relative permeability greater than one) but that cannot be magnetized (e.g., soft ferrites). Such an array configuration may be advantageous, but can produce a counter-torque acting against the torque produced by an external magnetic field on the magneto-mechanical oscillators. This counter-torque will be generally added to the torque of the torsion spring. This counter-torque may be used as a restoring force to supplement that of the torsion spring or to be used in the absence of a torsion spring in the magneto-mechanical oscillator. In addition, the counter-torque may reduce the degrees of freedom in configuring the plurality of magneto-mechanical oscillators.

FIG. 18 illustrates a torsional double hinge magneto-mechanical oscillator 1800, in accordance with some exemplary implementations. The double hinge magneto-mechanical oscillator 1800 may be incorporated as part of an array of magneto-mechanical oscillators as described above and further below. The double hinge magneto-mechanical oscillator 1800, as well as any of the other implementations described below, may be used as part of a wireless power receiver device or a wireless power transmission device. As shown in FIG. 18, the oscillator 1800 comprises a first base support element 1802, a second base support element 1804, a first torsional beam 1806 connected to the first base support element 1802, a second torsional beam 1808 connected to the second base support element 1804, a holder 1810 (e.g., a substrate or other material to which one or more additional materials or layers may be attached) connected to each of the first and second torsional beams 1806/1808 and a magnetic element 1812 disposed on the holder 1810. In some implementations, the magnetic element 1812 is a permanent magnet. In some implementations the holder 1810 may be referred to as or configured as a carrier. For example the carrier or holder 1810 may be an elastically movable carrier.

Although shown having a substantially square or rectangular cross-section, the first and second torsional beams 1806/1808 may have a substantially circular cross-section, which may provide a more uniform strain within the torsional beams 1806/1808 as well as increase the Q factor of the oscillator 1800. Moreover, by rounding the edges of the first and second torsional beams 1806/1808, a mechanical stress at the connection points between the first and second torsional beams 1806/1808 and either the bases 1802/1804 or the holder 1810 may be reduced. The magnetic element 1812 and the holder 1810 material may be chosen for good adhesion to one another. Each of the first and second base support elements 1802/1804 may be structurally fixed to a substrate (not shown in FIG. 18).

The holder 1810 and the magnetic element 1812 may be configured to oscillate about an axis defined through the long direction of extension of the first and second torsional beams 1806/1808, as shown by the arrows. For this reason, the magnetic element 1812 and/or the holder 1810 may be considered “moveable” or “rotatable.” The use of the first and second base support elements 1802/1804 provides a physical offset of the first and second beams 1806/1808, the holder 1810 and the magnetic element 1812 from a substrate (not shown) such that the holder 1810 and the magnetic element 1812 may be deflected at larger angles, with respect to a resting position, without the holder 1810 and/or magnetic element 1812 contacting the substrate and causing damage. In order to achieve the highest degree of coupling to an external magnetic field that excites the oscillator 1800, the magnetic element 1812 may be magnetized in a direction perpendicular to the first and second torsional beams 1806/1808 and in a plane defined by the holder 1810, as shown by the arrow on the magnetic element 1812.

In at least some implementations, the first and second bases 1802/1804, the first and second torsional beams 1806/1808, and the holder 1810 may be formed from the same material, e.g., from silicon, so that a single structuring process may be utilized and sufficient mechanical stability may be achieved. The magnetic element 1812 may then be deposited on the holder 1810. As compared to a first thickness, the magnetic element 1812 may be deposited to have an increased thickness, where the formation process allows, in order to increase the magnetic moment of the magnetic element 1812, and so the magnetic moment of the oscillator 1800. In addition, the dimensions of the holder 1810, magnetic element 1812, and the torsional beams 1806/1808 may be determined to optimize (e.g., increase as much as possible or practical) the fill factor of the magnetic element 1812 with respect to the dimensions of the oscillator 1800, to provide a desired mechanical resonance frequency of the oscillator 1800, and/or to increase mechanical stability and resilience to stress of the oscillator 1800.

FIG. 19 illustrates a torsional double hinge magneto-mechanical oscillator 1900, in accordance with some other exemplary implementations. As shown in FIG. 19, the torsional double hinge oscillator 1900 comprises a first base support element 1902, a second base support element 1904, a first torsional beam 1906 connected to the first base support element 1902, a second torsional beam 1908 connected to the second base support element 1904, a holder 1910 connected to each of the first and second torsional beams 1906/1908 and a layer of magnetic material 1912 disposed on the holder 1910, as previously described in connection with FIG. 18. However, as compared to the magnetic material 1812 of FIG. 18, the magnetic material 1912 may have an increased height “h” and/or length “l”, and a reduced width “w”. This may provide a larger gyromagnetic ratio and density of magnetic moment, as compared to the implementation shown in FIG. 18. For example, increasing the length “l” of the magnetic material 1912 may maintain the moment of inertia per volume at a constant level while fill factor or packing density of the oscillators 1900 may increase as compared to FIG. 18. Moreover, it may be desirable to increase the height “h” of the magnetic material 1912 within constraints given by the demagnetization field, the magnetic material 1912 used, and the direction of magnetization.

As previously described in connection with FIG. 18, the magnetic material 1912 may have a direction of magnetization that is perpendicular to the axis defined by the length of extension of the first and second torsional beams 1906/1908, as shown by either of the heavy arrows on the magnetic element 1912 (e.g., along the “h” or “w” axes. This may result in a maximum torque on the oscillator when driven by the exciting external magnetic field. For magnetization of an exemplary NdFeB magnetic element, optimal ratios of “l”/“w” and “l”/“h” for the magnetic element 1912 may be close to 2, but should generally not exceed 3 to preserve stability in the direction of magnetization of the magnetic element 1912.

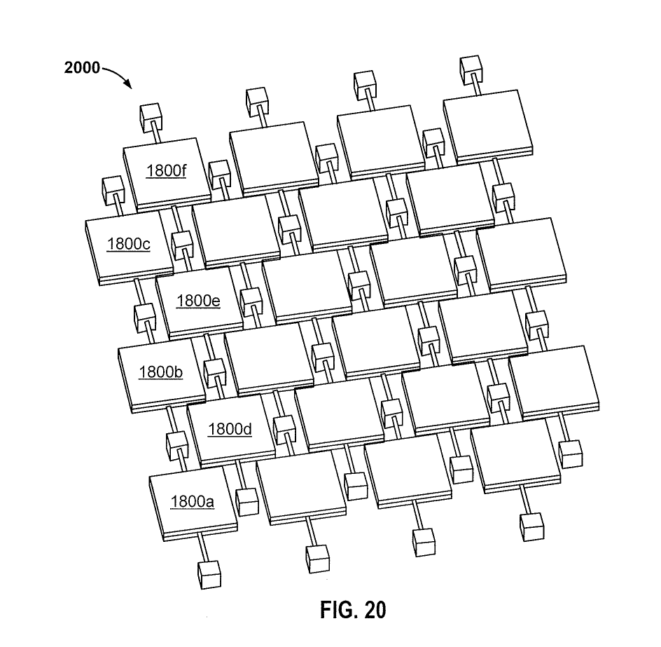

FIG. 20 illustrates a 2-dimensional nested array 2000 of the torsional double hinge magneto-mechanical oscillators 1800/1900 of FIG. 18 and FIG. 19, in accordance with some exemplary implementations. As shown in FIG. 20, the nested array 2000 may comprise a plurality of oscillators 1800a-1800f aligned into a plurality of nested rows of oscillators. The nested rows may be offset from one another. In some implementations, the oscillators 1800a-1800f may be substantially identical to one another in order to resonate substantially at the same natural frequency, considering fabrication tolerances. The nested arrangement allows the use of empty space between magnetic elements (and holders) of a particular nested row of oscillators for base support elements and torsional beams of an adjacent row of oscillators. For example, oscillators within a particular row (e.g., oscillators 1800a-1800c) may be offset in a direction parallel to the axis of oscillation by approximately half of a pitch of an oscillator. In this way, the holder and magnetic element of oscillators in a particular row of oscillators may be immediately adjacent to (e.g., nested by) the base support elements and torsional beams of oscillators in an immediately adjacent row of oscillators. In order to minimize frictional forces and thus increase the Q-factor of the array 2000, the empty space between individual oscillators may be quasi-evacuated of air or may be filled with a special gas at low pressure (e.g., inert gases such as nitrogen or xenon).

As previously described in connection with FIGS. 18 and 19, each of the oscillators may have a direction of magnetization perpendicular to the axis of oscillation, and may be either substantially in the plane of the holder or substantially perpendicular to the plane of the holder. Moreover, depending on the particular implementation, the direction of magnetization may be the same for all oscillators in the array 2000 (e.g., a ferromagnetic arrangement), the direction of magnetization may alternate directions for adjacent oscillators (e.g., an anti-ferromagnetic arrangement) such that the array 2000 may exhibit a substantially zero aggregate magnetic field component a certain distance from the array 2000, or the direction of magnetization of the oscillators may be random (e.g., a paramagnetic arrangement) such that the aggregate magnetic field component will statistically cancel out across the entire array 2000, at the certain distance from the array 2000.

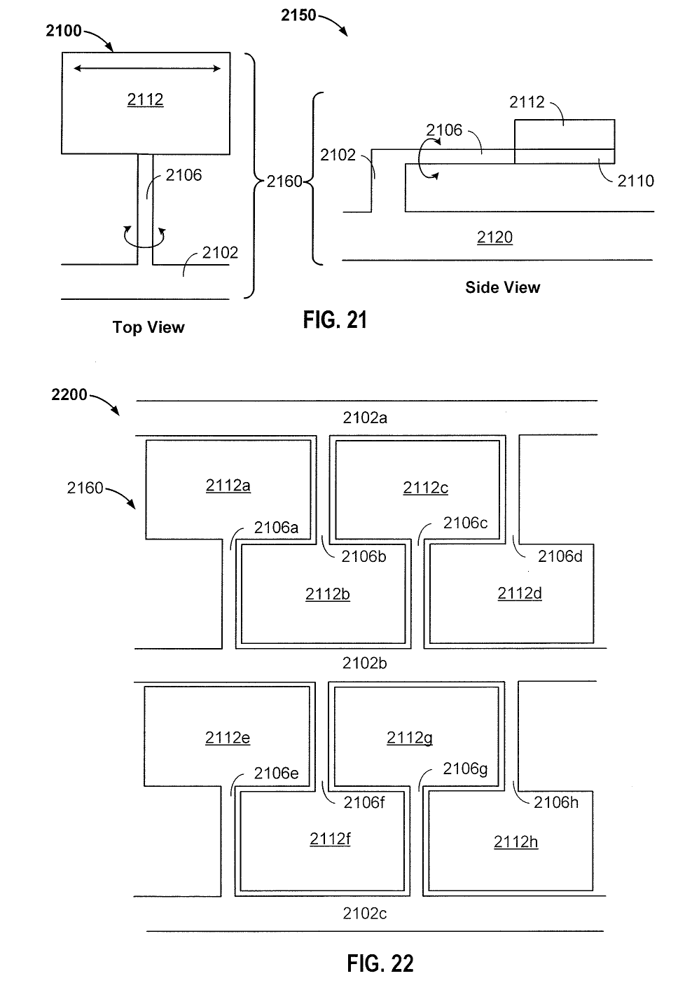

FIG. 21 illustrates a top view 2100 and a side view 2150 of a torsional magnetic single hinge magneto-mechanical oscillator 2160, in accordance with some exemplary implementations. The single hinge magneto-mechanical oscillator 2160 may be incorporated as part of an array of magneto-mechanical oscillators as described above and further below and may be used as part of a wireless power receiver device or a wireless power transmission device in accordance with implementations described herein. As shown in the top view 2100 of FIG. 21, the oscillator 2160 may comprise a base support element 2102, a single torsional beam 2106 connected to a holder 2110 (see side view 2150) and a magnetic element 2112 disposed on the holder 2110. As shown in the side view 2150, the base support element 2102 may be disposed on a substrate 2120. In an implementation, the holder 2110 and the magnetic element 2112 may be configured to oscillate about an axis that is parallel to the direction of extension of the torsional beam 2106, as shown by the curved double-headed arrows. In such implementations, the preferred direction of magnetization of the magnetic element 2112 is in the plane of the holder 2110 and perpendicular to the axis of rotation (e.g., perpendicular to the direction of extension of the torsional beam 2106), as shown by the straight double-headed arrow in the top view 2100. However, there are also two other cantilever oscillation modes. A first may comprise oscillation back and forth in a left to right motion for the top view 2100. The second may comprise oscillation up and down as viewed in the side view 2150.

FIG. 22 illustrates a 2-dimensional nested array 2200 of the torsional magnetic single hinge magneto-mechanical oscillator 2160 of FIG. 21, in accordance with some exemplary implementations. As shown in FIG. 22, the array 2200 may comprise a plurality of nested oscillators 2160. Torsional beams 2106a-2106h may be connected to a particular one of the base support elements 2102a-2102c in an alternating orientation such that adjacent torsional beams 2106a/f are connected on opposite sides of the particular base support element 2102b, for example. Moreover, the holders and magnetic elements 2112a/c for each oscillator 2160 are nested with holders and magnetic elements 2112b/d of adjacent oscillators 2160. For example, a space between adjacent magnetic elements connected to the same base support element 2102b may be filled with the torsional beams 2106b/d of oscillators 2160 connected to adjacent base support elements 2102a, for example. Utilizing common base support elements 2102a-c may allow the base support elements 2102a-c to be designed with higher rigidity, thus being more stress and flex resistant, improving the Q-factor of the array 2200. Moreover, as previously described in connection with the array 2000 of FIG. 20, the magnetic elements 2112a-h of each of individual oscillators 2160 may have directions of magnetization with respect to each other in one of the ferromagnetic arrangement, the anti-ferromagnetic arrangement, and the paramagnetic arrangement.

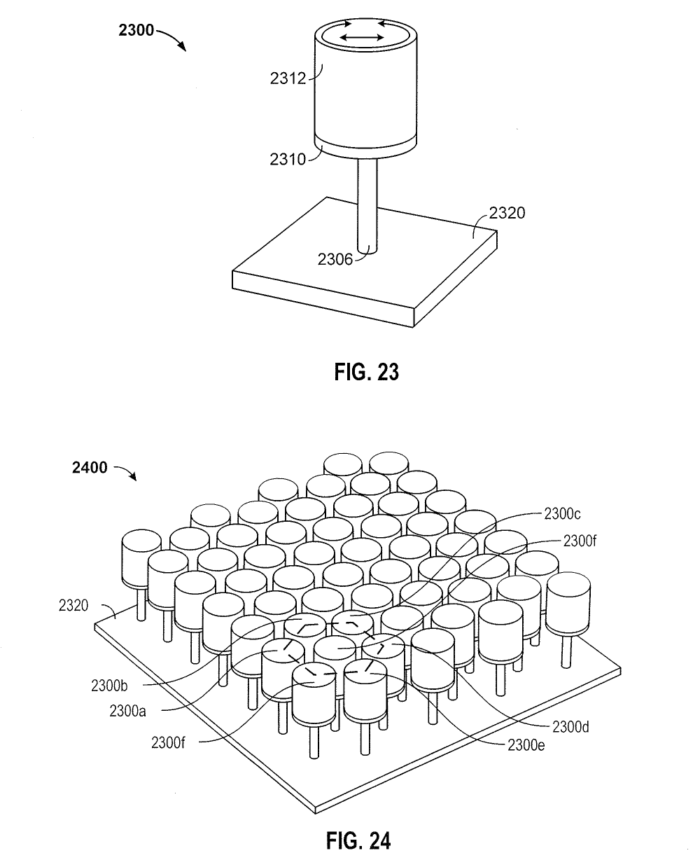

FIG. 23 illustrates a torsional in-plane magneto-mechanical oscillator 2300, in accordance with some exemplary implementations. As shown in FIG. 23, the oscillator 2300 may comprise a substrate 2320, a torsional beam 2306 disposed on and connected in a perpendicular direction to the substrate 2320. A circular holder 2310 may be disposed on and connected to the torsional beam 2306. A cylindrical magnetic element 2312 may be disposed on and connected to the holder 2310. Although shown having a cylindrical cross section, the present application is not so limited and the holder 2310 and the magnetic element 2312 may have any cross sectional shape. The magnetic element 2312 may have a direction of magnetization in a direction parallel to the plane of the holder 2310 and the substrate 2320, as shown by the double arrowed straight line. Under the influence of an external alternating magnetic field, the magnetic element 2312 may be configured to oscillate about an axis parallel with the direction of extension of the torsional beam 2306 (e.g., the oscillatory axis is perpendicular to the plane of the substrate 2320 and to the plane of the holder 2310, as shown by the double-headed curved arrow). In some implementations, in order to ensure sufficient rigidity and robustness of the oscillator 2300, each of the substrate 2320, the torsional beam 2306, and the holder 2310 may be formed of the same material (e.g., silicon) utilizing a photolithographic process, for example.

The oscillator 2300 of FIG. 23 may be fabricated in a two-dimensional array, as described in connection with FIG. 24 below. FIG. 24 illustrates a 2-dimensional array 2400 of the torsional in-plane magneto-mechanical oscillators 2300 of FIG. 23, in accordance with some exemplary implementations. The array 2400 may comprise a plurality of torsional in-plane magneto-mechanical oscillators 2300a-2300f arranged in a hexagonal pattern to provide a highest possible packing density (e.g., each row of oscillators is offset from an adjacent row of oscillators in a direction of the rows extension by approximately half of the pitch between oscillators in a row). In some other implementations, adjacent rows may not be offset in the direction of row extension, and instead may be packed with a substantially rectangular or square pattern at the expense of packing density.

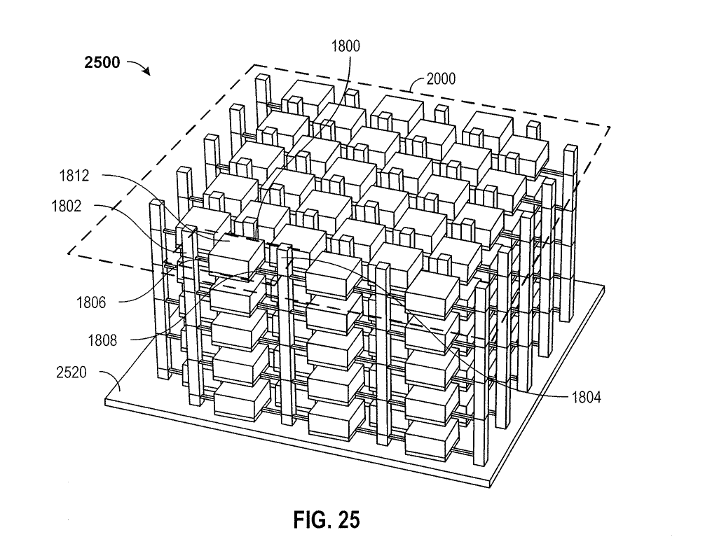

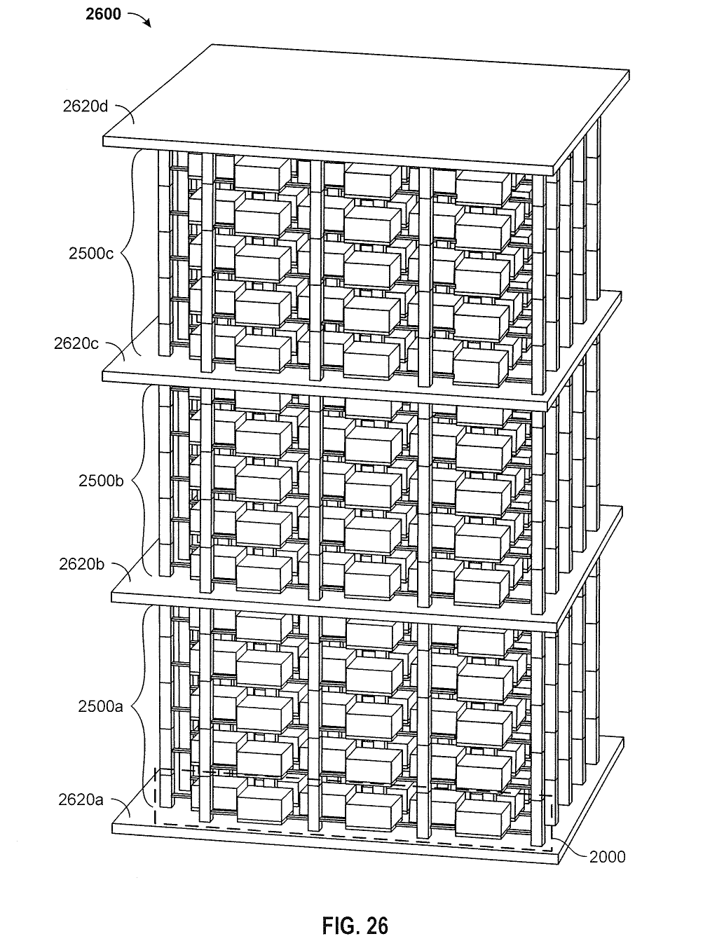

The torsional magneto-mechanical oscillators as previously described in connection with FIGS. 18-22 may be assembled into 3-dimensional arrays by either stacking finished 2-dimensional arrays (see FIGS. 20, 22) including the substrate, or alternatively, by applying the same process repetitively on the same substrate in a manner similar to constructing a multi-story building, as will be described in more detail in connection with FIGS. 25 and 26 below.

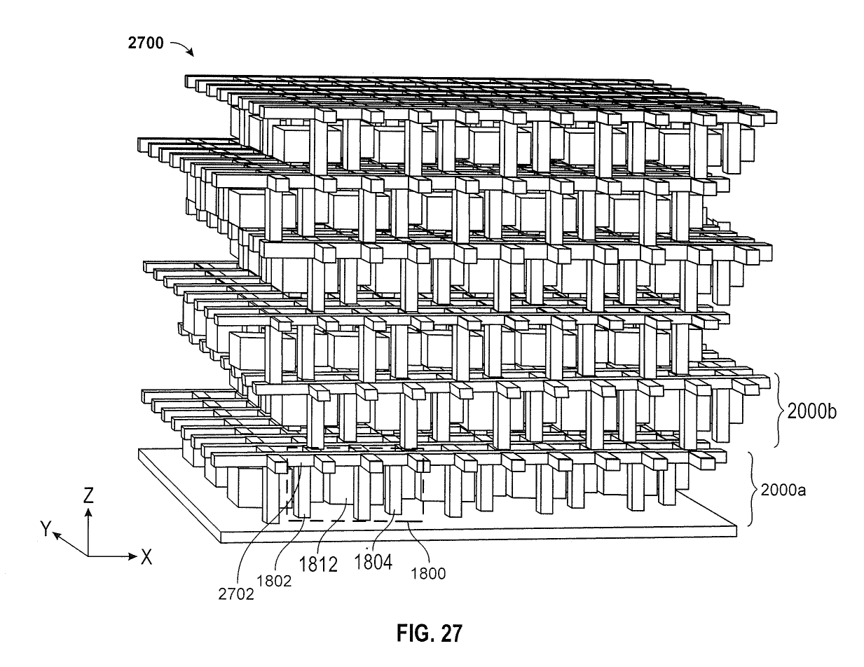

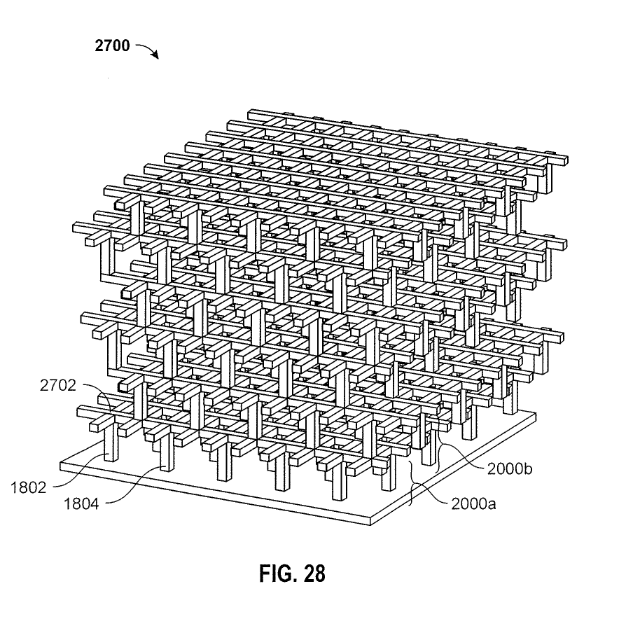

FIG. 25 illustrates a 3-dimensional array 2500 of the torsional magneto-mechanical oscillators of any of FIGS. 18-22, in accordance with some exemplary implementations. As shown in FIG. 25, the 3-dimensional array 2500 comprises a plurality of 2-dimensional arrays 2000 of the oscillators 1800 as previously described in connection with FIGS. 20 and 18, respectively. In FIG. 25, the 2-dimensional arrays 2000 are stacked one on top of another in a direction perpendicular to the planes of the 2-dimensional arrays 2000. In such implementations, the base support elements 1802/1804 of each 2-dimensional array 2000 may merge into support pillars. These pillars provide structural support for the torsional beams 1806/1808 as well as mechanical stability and rigidity for the 3-dimensional array 2500 as a whole. Mechanical stability may be improved by using at least one of the following: 1) introduction of additional structural layers (see FIG. 26), 2) bonding the structural layers by additional structural elements perpendicular to the structural layers (see FIGS. 27 and 28), and 3) introduction of structural networks incorporating the base support elements (see FIGS. 27 and 28).

FIG. 26 illustrates a 3-dimensional array 2600 of the torsional magneto-mechanical oscillators of any of FIGS. 18-22 and 25, in accordance with some exemplary implementations. As shown in FIG. 26, the 3-dimensional array 2600 may be substantially the same as the 3-dimensional array 2500 of FIG. 25, however, further comprising a plurality of additional substrates 2620a, 2620b, 2620c, 2620d inserted after every “N” layers of the 2-dimensional arrays 2000, as previously described in connection with FIGS. 20 and 25. Thus, the “building” of the 3-dimensional array 2600 may comprise a plurality of “stories” each comprising a 3-dimensional array 2500a-2500d as shown in FIG. 25, and each separated from the next by a substrate 2620a-2620d. The substrates 2620a-2620d may be made of silicon or from another material having a higher rigidity.

FIG. 27 illustrates a 3-dimensional array 2700 of the torsional magneto-mechanical oscillators of any of FIGS. 18-22 and 25, in accordance with some exemplary implementations. The 3-dimensional array 2700 may be substantially the same as the 3-dimensional array 2500 of FIG. 25, however, each 2-dimensional array (e.g., array 2000a), comprising a plurality of oscillators 1800, may be offset from an adjacent 2-dimensional array (e.g., array 2000b) in one or both of the “x” direction and the “y” direction by connecting base support elements 1802/1804 within a particular 2-dimensional array 2000a/2000b to one another utilizing horizontal (e.g., perpendicular) support beams 2702 extending in one or both of the “x” direction and the “y” direction. In this way, the base support elements 1802/1804 of adjacent 2-dimensional arrays 2000a/2000b are offset from one another, while providing increased structural rigidity to the 3-dimensional array 2700.

FIG. 28 illustrates the 3-dimensional array 2700 of FIG. 27 showing only the support structure, in accordance with some exemplary implementations. As shown in FIG. 28, the 3-dimensional array 2700 comprises the base support elements 1802/1804 connected to one another via the perpendicular support beams 2702 extending between base support elements in one or both orthogonal directions that are in-plane with each 2-dimensional array 2000a/2000b.

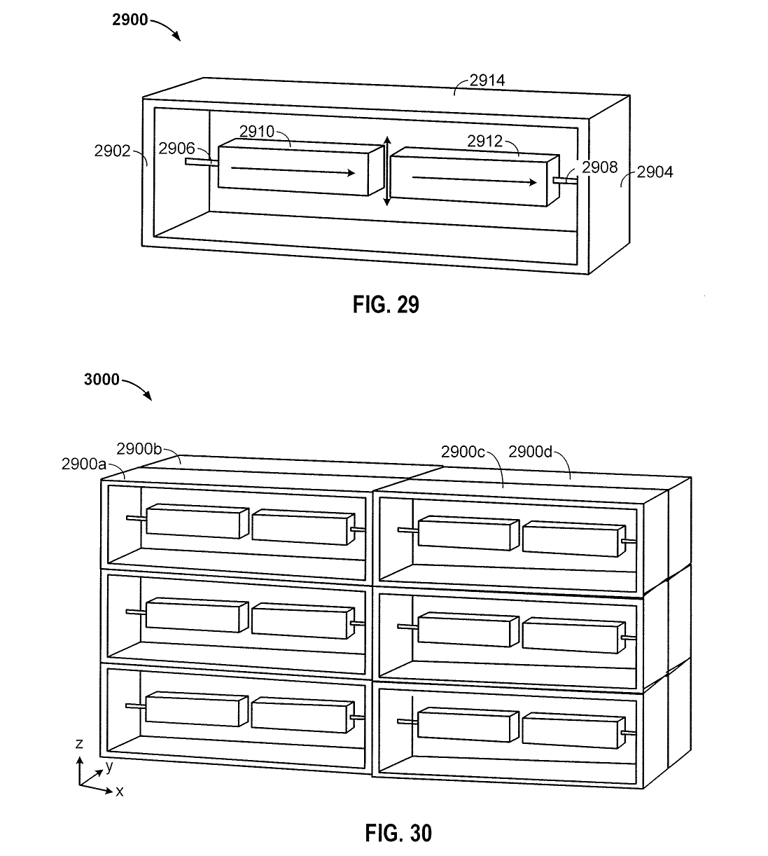

FIG. 29 illustrates a partially levitating double magnetic element magneto-mechanical oscillator 2900, in accordance with some exemplary implementations. As shown in FIG. 29, the oscillator 2900 comprises a first base support element 2902, a second base support element 2904, a first anchor beam 2906 connected to the first base support element 2902, a second anchor beam 2908 connected to the second base support element 2904, a first magnetic element 2910 connected to the first anchor beam 2906, and a second magnetic element 2912 connected to the second anchor beam 2908. The first and second magnetic elements 2910/2912 may have the same direction of magnetization, as shown by the single-headed arrows, and may additionally have the same orientation as one another. The first and second magnetic elements 2910/2912 may be separated from one another by a small gap such that they attract one another sufficiently to provide a restoring force that may hold the first and second magnetic elements 2910/2912 in a substantially zero displacement position regardless of the direction of gravity. This condition may be known as “partial levitation.” Thus, the first 2910 and second 2912 magnetic elements are levitated by the attraction between the first 2910 and second 2912 magnetic elements. The first and second anchor beams 2906/2908 may comprise a string or spring that radially constrains the possible motion of the first and second magnetic elements 2910/2912 around an anchor point on the first and second base support elements 2902/2904, respectively. As shown in FIG. 29, the first and second base support elements 2902/2904 may be a part of a support structure and enclosure 2914.

FIG. 30 illustrates a 3-dimensional array 3000 of the partially levitating double magnetic element magneto-mechanical oscillators 2900 of FIG. 29, in accordance with some exemplary implementations. As shown in FIG. 30, a plurality of the oscillators 2900a-2900d may be stacked in one or more of the 3 orthogonal directions, “x”, “y”, and “z” to form a 2- or 3-dimensional array 3000.

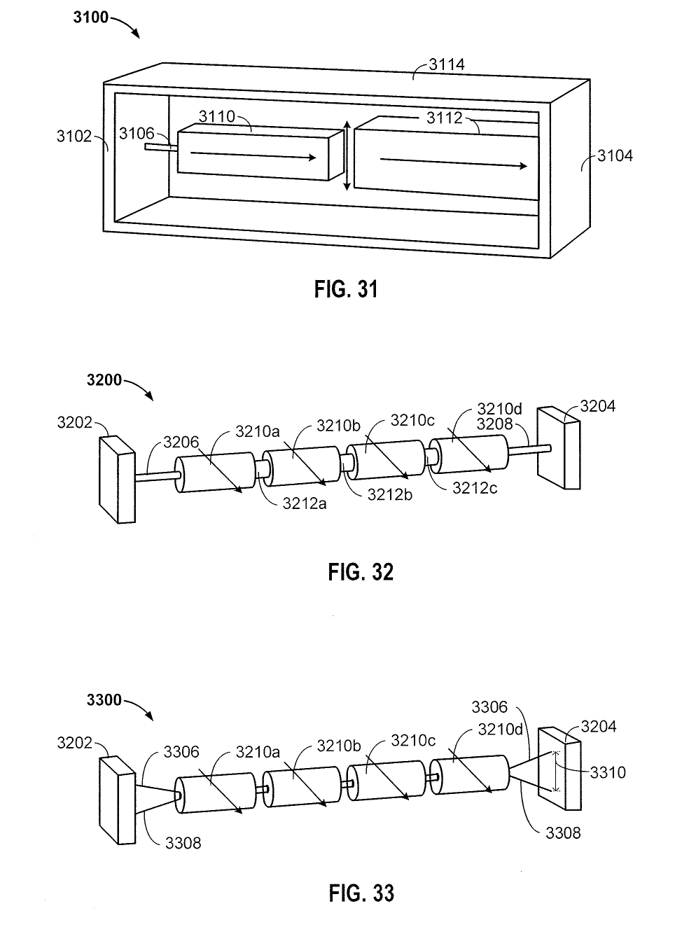

FIG. 31 illustrates a partially levitating single magnetic element magneto-mechanical oscillator 3100, in accordance with some exemplary implementations. As shown in FIG. 31, the partially levitating single magnetic element oscillator 3100 may comprise first and second base support elements 3102/3104, first and second magnetic elements 3110/3112, a first anchor beam 3106 and a support structure and/or enclosure 3114. Each of the above-mentioned pieces of the oscillator 3100 may be substantially the same as described for the partially levitating double magnetic element oscillator 2900 of FIG. 29 with the exception that the second magnetic element 3112 is not connected to the second base support element 3104 by an anchor beam. Instead, the second magnetic element 3112 may be fixed to the second base support element 3104. In some implementations, the 3-dimensional array of oscillators may be formed by stacking a plurality of the oscillators 3100 in one or more of the “x,” “y,” and “z” directions, as previously described in connection with FIG. 30.

In some implementations, the gyromagnetic ratio and density of magnetic moment of an oscillator may be increased by rigidly connecting a number of magnets, oscillating about a common axis of oscillation, with non-magnetic beams, spacers, or strings. Such implementations may be called torsional magneto-mechanical chain oscillators. In such implementations, for example as those shown in FIGS. 32-37, in a transmitter, an excitation circuit may generate a first alternating magnetic field. The first alternating magnetic field imparts a force or torque to the magnets, which causes them to oscillate about the common axis of oscillation. This oscillation generates a second alternating magnetic field, which may in turn induce a force or torque on a second set of magnets in a receiver. This induced force or torque causes the second set of magnets in the receiver to oscillate, generating a third alternating magnetic field. This third alternating magnetic field may be harvested by a receiver circuit configured to generate an alternating electric current for charging or powering a load under the influence of the third alternating magnetic field.

FIG. 32 illustrates a torsional magneto-mechanical chain oscillator 3200, in accordance with some exemplary implementations. As shown in FIG. 32, the oscillator 3200 may comprise first and second base support elements 3202/3204 connected to first and second torsional beams 3206/3208, respectively. A plurality of magnetic elements 3210a/3210b/3210c/3210d may be connected between the first and second torsional beams 3202/3204 and to one another by non-magnetic spacers 3212a/3212b/3212c. In some implementations, the magnetic elements 3210a-3210d may each have a cylindrical cross-section to minimize the inertial moment and maximize the fill factor. The torsional beams 3206/3208 may provide the restoring force for the oscillator 3200. The spacers 3212a-3212c may reduce the effect of the demagnetization field since the demagnetization field may not allow for diametrical magnetization of a single magnetic cylinder having the same length as the chain. Moreover, rigidly connecting the magnetic elements 3210a-3210d may not change the total inertial moment of an array, but may increase the fill factor and thus the density of the magnetic moment and the gyromagnetic ratio. This is mainly due to the fact that only two torsional beams 3206/3208 are used for an arbitrary number of magnetic elements in the chain. This may also simplify a fabrication process. In the implementations of FIG. 32, each of the magnetic elements 3210a-3210d may have a same direction of magnetization, as shown by the arrows.

In some implementations, the magnetic elements 3210a-3210d within each chain oscillator may be spaced from one another by a distance greater than the length of the magnetic elements and adjacent chain oscillators may be located close enough to one another that a “nested” arrangement may be achieved, similar to that previously described in connection with FIGS. 20 and 22. For example, the magnetic elements of one chain oscillator may be disposed adjacent to the spacers of an adjacent chain oscillator and between at least a portion of two adjacent magnetic elements in the adjacent chain oscillator. This serves to increase the fill factor in directions perpendicular to the axis of the chain oscillators, though the oscillators' lengths may be greater than in other implementations in order to accommodate the increased spacing between the magnetic elements of a particular chain oscillator. In some other implementations, the torsional beams 3206/3208 may be replaced with spiral springs.

FIG. 33 illustrates a torsional magneto-mechanical chain oscillator 3300, in accordance with some other exemplary implementations. As shown in FIG. 33, the oscillator 3300 may comprise each element as previously described in connection with FIG. 32, except that the first and second beams 3206/3208 are replaced with first and second strings 3306/3308 that are threated through the plurality of magnetic elements 3210a/3210b/3210c/3210d and the magnetic elements are no longer connected to one another by the non-magnetic spacers 3212a/3212b/3212c. The first and second strings 3306/3308 may be anchored or connected to each of the first and second base support elements 3202/3204 a predetermined distance 3310 from one another. Thus, the first and second strings 3306/3308 may provide the restoring force for the oscillator 3300. A tension in the strings 3306/3308 may be adjusted to modify or tune the mechanical resonance frequency of the chain oscillator. In some implementations, the strings 3306/3308 may comprise an elastic material, e.g., spring steel, nylon, carbon, etc. However, to preserve high Q-factors, the torsion of the strings should not cause substantial friction, e.g., at the contact points with the magnetic elements 3210a-3210d. Thus, the magnetic elements 3210a-3210d may be rigidly bonded to the string pair. In such implementations the magnetic elements 3210a-3120d may have different directions of magnetization from one another. For example, the magnetic elements 3210a-3210d may have alternating and opposite directions of magnetization (e.g., a within-oscillator anti-ferromagnetic arrangement). In such implementations, the net inertial moment of (and sum of all torques within) each chain oscillator may be substantially zero when the number of magnetic elements in a particular chain oscillator are even. In yet other implementations, rather than a pair of strings 3306/3308, only a single string may be utilized to suspend the plurality of magnetic elements 3210a-3210d between the first and second base support elements 3202/3204.

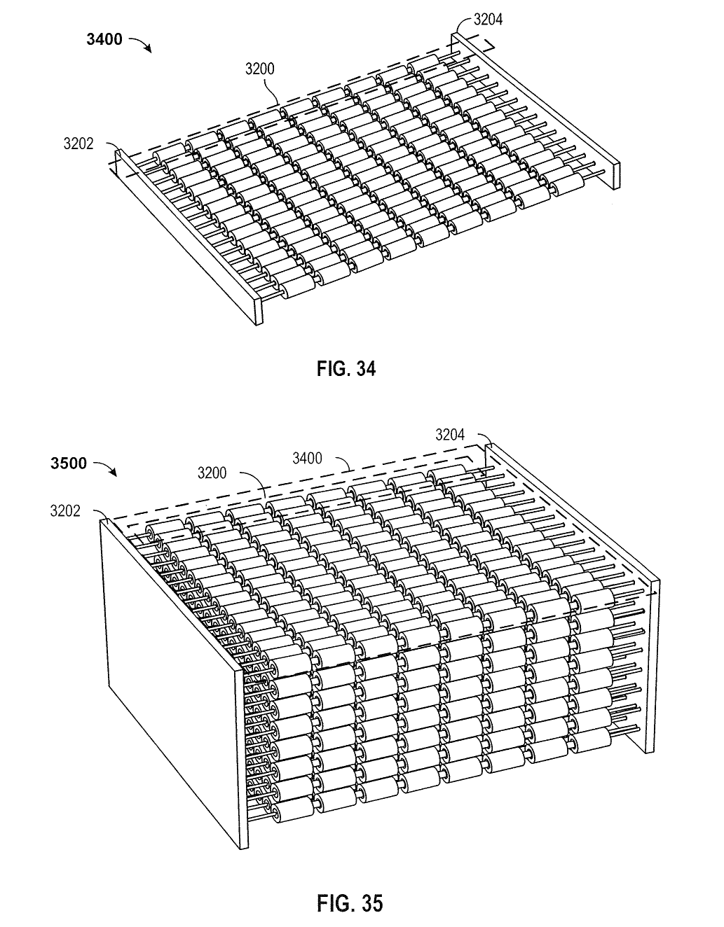

FIG. 34 illustrates a 2-dimensional array 3400 of the torsional magneto-mechanical chain oscillators 3200 of FIG. 32. As shown in FIG. 34, the 2-dimensional array 3400 may comprise the first base support element 3202, the second base support element 3204, and a plurality of torsional magneto-mechanical chain oscillators 3200, each connected between the first and second base support elements 3202/3204. Although the magnetic elements within each oscillator 3200 have the same direction of magnetization, adjacent oscillators 3200 may have relative directions of magnetization including any of the previously described ferromagnetic arrangement, the anti-ferromagnetic arrangement, and the paramagnetic arrangement.

FIG. 35 illustrates a 3-dimensional array 3500 of the torsional magneto-mechanical chain oscillators 3200 of FIG. 32. As shown in FIG. 35, the 3-dimensional array 3500 may comprise the first base support element 3202, the second base support element 3204, and a plurality of 2-dimensional arrays 3400 comprising the torsional magneto-mechanical chain oscillators 3200/3300, as shown in FIGS. 32/33. Each of the individual oscillators 3200/3300 are connected between the first and second base support elements 3202/3204. Although the magnetic elements within each oscillator 3200/3300 have the same direction of magnetization, adjacent oscillators 3200/3300 may have relative directions of magnetization including any of the previously described ferromagnetic arrangement, the anti-ferromagnetic arrangement, and the paramagnetic arrangement.

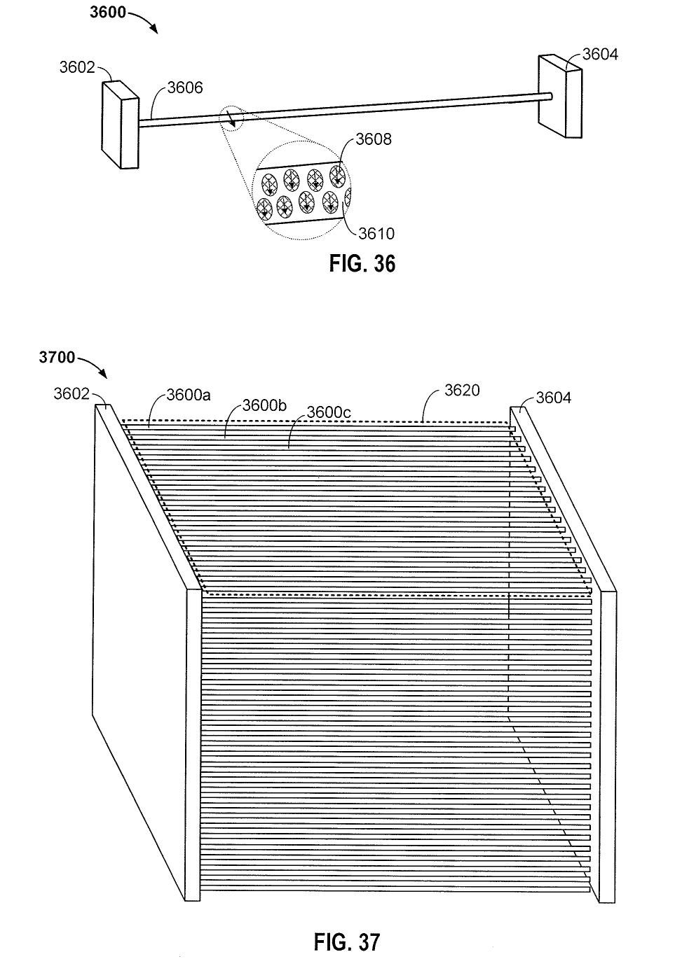

FIG. 36 illustrates a torsional magneto-mechanical chain oscillator 3600, in accordance with yet other implementations. As shown in FIG. 36, the chain oscillator 3600 may comprise first and second base support elements 3602/3604 connected to a magnetized string 3606. In some implementations, the magnetized string 3606 may comprise a heterogeneous magneto-elastic string. In some implementations, the string 3606 may be fabricated by extrusion of a melt comprising a mix of elastic and ferromagnetic components. As shown in FIG. 36, the string 3606 may comprise a polyamide melt 3610 that includes a plurality of ferromagnetic particles 3608. The ferromagnetic particles 3608 may each have a direction of magnetization such that the string 3606 exhibits a net direction of magnetization that is diametric (e.g., the direction of magnetization is in a direction of the diameter of the string 3606, as shown by the arrows). In some other implementations, rather than comprising a heterogeneous mixture of elastic and ferromagnetic components, the string 3606 may comprise a homogeneous magnetic material that allows for at least a portion (e.g., a majority) of the string 3606 to have a diametric direction of magnetization.

FIG. 37 illustrates a 3-dimensional array 3700 of the torsional magneto-mechanical chain oscillators 3200 of FIG. 35. As shown in FIG. 37, a plurality of torsional magneto-mechanical chain oscillators 3600a, 3600b, 3600c may form a 2-dimensional array 3520 of the torsional magneto-mechanical chain oscillators 3600a-3600c. A plurality of the 2-dimensional arrays 3520 may be stacked or fabricated one next to, or adjacent to, another to form the 3-dimensional array 3700. As previously described with respect to other implementations, each of the oscillators 3600a-3600c may have diametric directions of magnetization that are all the same (e.g., ferromagnetic), that alternate from oscillator to oscillator (e.g., anti-ferromagnetic), or that are randomly distributed throughout the array 3700 (e.g., paramagnetic).

Accordingly, with respect to FIGS. 32-37 for chain oscillator implementations, at least some implementations configured in either a wireless power transmitter or receiver device may be as provided below:

1. An apparatus for transferring power wirelessly, comprising:

a plurality of magneto-mechanical oscillators, each comprising:
first and second base support elements disposed on a substrate; and
a chain comprising a plurality of magnetic elements suspended between the first and second base support elements.

2. The apparatus of claim 1, wherein the chain comprises a first beam connecting a first end of the chain to the first base support element and a second beam connecting a second end of the chain to the second base support element.

3. The apparatus of claim 1, wherein the chain comprises one or more strings threaded through each of the plurality of magnetic elements and connecting a first end of the chain to the first base support element and a second end of the chain to the second base support element.

4. The apparatus of any of claims 1-3, wherein a direction of magnetization of each of the plurality of magnetic elements alternates along the chain.

5. The apparatus of any of claims 1-3, wherein a direction of magnetization of each of the plurality of magnetic elements is the same.

6. The apparatus of any of claims 1-5, wherein an orientation of each of the plurality of magnetic elements is fixed with respect to adjacent magnetic elements in the chain.

7. The apparatus of any of claims 1-5, wherein each of the plurality of magnetic elements is free to rotate around a linear axis of the chain with respect to adjacent magnetic elements in the chain.

8. The apparatus of any of claims 1-7, wherein the chain comprises an elastic material and each of the plurality of magnetic elements comprises a plurality of magnetic particles embedded in the elastic material.

9. The apparatus of any of claims 1-8, wherein the excitation circuit further comprises at least one coil surrounding at least a portion of the plurality of oscillators and is configured to generate the first magnetic field by flowing an electrical current through the at least one coil.

10. The apparatus of any of claim 1-9, wherein the plurality of oscillators are arranged in at least one two-dimensional array comprising a plurality of nested chains such that magnetic elements on a particular chain are disposed in spaces between adjacent magnetic elements on an adjacent chain.

11. The apparatus of claim 10, wherein the at least one two-dimensional array comprises a plurality of two-dimensional arrays arranged in a three-dimensional array.

In addition, with respect to FIGS. 32-37 for chain oscillator implementations, methods in accordance with at least some implementations may be as provided below:

1. A method of transferring power wirelessly, the method comprising:

generating a first time-varying magnetic field via movement of a plurality of magnetic elements arranged in a chain in each of a plurality of magneto-mechanical oscillators under the influence of a second time-varying magnetic field.

2. The method of claim 1, wherein the chain comprises a first beam connecting a first end of the chain to a first base support element and a second beam connecting a second end of the chain to a second base support element.

3. The method of claim 1, wherein the chain comprises one or more strings threaded through each of the plurality of magnetic elements and connecting a first end of the chain to a first base support element and a second end of the chain to a second base support element.

4. The method of any of claims 1-3, wherein a direction of magnetization of each of the plurality of magnetic elements alternates along the chain.

5. The method of any of claims 1-3, wherein a direction of magnetization of each of the plurality of magnetic elements is the same.

6. The method of any of claims 1-5, wherein an orientation of each of the plurality of magnetic elements is fixed with respect to adjacent magnetic elements in the chain.

7. The method of any of claims 1-5, wherein each of the plurality of magnetic elements is free to rotate around a linear axis of the chain with respect to adjacent magnetic elements in the chain.

8. The method of any of claims 1-7, wherein the chain comprises an elastic material and each of the plurality of magnetic elements comprises a plurality of magnetic particles embedded in the elastic material.

9. The method of any of claims 1-8, wherein generating the first magnetic field comprises flowing an electrical current through at least one excitation circuit comprising at least one coil surrounding at least a portion of the plurality of oscillators.

10. The method of any of claims 1-9, wherein generating the second magnetic field further comprises, in each oscillator of the plurality of oscillators, rotating each of the plurality of magnetic elements about an axis of the chain in response to a torque applied to the plurality of magnetic elements by the first magnetic field.

11. The method of any of claims 1-10, further comprising applying a restoring force to the plurality of magnetic elements in response to rotation of the plurality of magnetic elements.

12. The method of any of claims 1-11, wherein the plurality of oscillators are arranged in at least one two-dimensional array comprising a plurality of nested chains such that magnetic elements on a particular chain are disposed in spaces between adjacent magnetic elements on an adjacent chain.

13. The method of claim 12, wherein the at least one two-dimensional array comprises a plurality of two-dimensional arrays arranged in a three-dimensional array.

14. A non-transitory, computer-readable medium comprising code that, when executed, causes an apparatus to perform a method according to any of claims 1-13 immediately above.

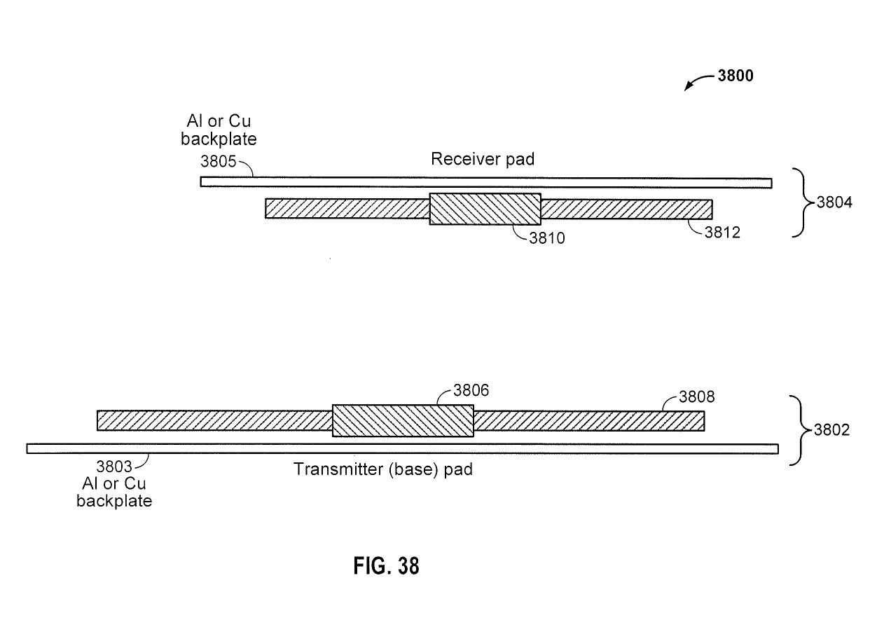

FIG. 38 schematically illustrates an example configuration 3800 of a power transmitter 3802 (e.g., a transmitter base pad coupled to an aluminum or copper back plate 3803) and a power receiver 3804 (e.g., a receiver pad coupled to an aluminum or copper back plate 3805), in accordance with some exemplary implementations. For planar low-profile designs for a power transfer pad, the power transmitter 3802 and/or the power receiver 3804 described herein may be used in which at least one coil and at least one disk comprising a plurality of magneto-mechanical oscillators is used. For example, the power transmitter 3802 can comprise at least one coil 3806 and at least one disk 3808 comprising a plurality of magneto-mechanical oscillators as described herein, and the power receiver 3804 can comprise at least one coil 3810 and at least one disk 3812 comprising a plurality of magnetic oscillators as described herein. Certain such configurations can lead to solutions that are analogous to a planar “solenoid” coil that uses a flat ferrite core (e.g., analogous to the at least one coil described herein) and a conductive back plate to shape the magnetic field. In certain such configurations, the system generates a substantially horizontal magnetic moment and may be characterized by a relatively strong coupling, even in misalignment conditions. As opposed to the “solenoid” configurations, certain implementations described herein have the potential for higher Q-factors and do not require tuning capacitors (e.g., by using a core that is self-resonant). Losses in certain implementations described herein may be reduced to eddy current losses, but virtually no hysteresis losses and copper losses.

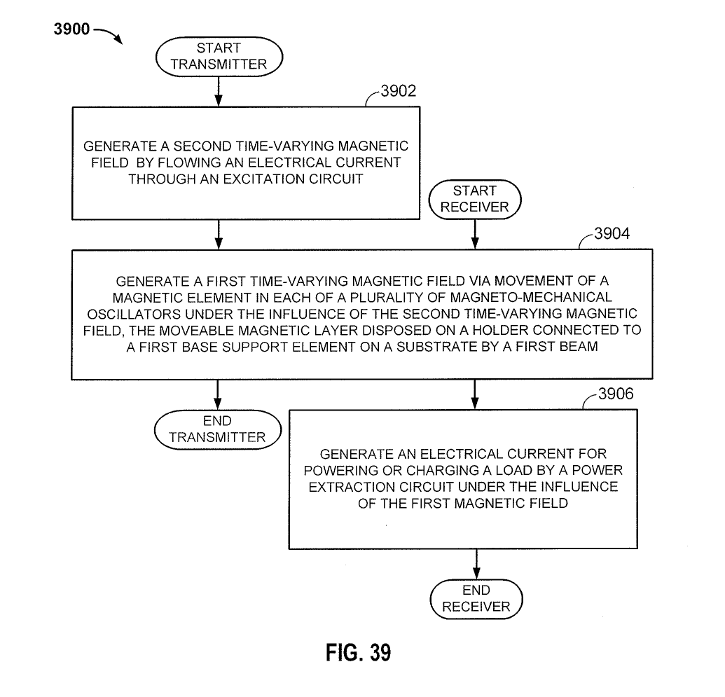

FIG. 39 is a flowchart 3900 of a method of transferring power wirelessly, in accordance with some exemplary implementations. In some implementations, one or more of the blocks (e.g., 3902, 3094) in flowchart 3900 may be performed by a wireless power transmitter, while one or more blocks (e.g., 3904, 3906) may be performed by a wireless power receiver. Although the flowchart 3900 is described herein with reference to a particular order, in various implementations, blocks herein may be performed in a different order, or omitted, and additional blocks may be added.

For wireless power transmitters, the flowchart 3900 may begin with operation block 3902, which includes generating a second time-varying magnetic field by flowing an electrical current through an excitation circuit. In some implementations, the excitation circuit comprises at least one coil surrounding at least a portion of a plurality of magneto-mechanical oscillators. The flowchart 3900 may then advance to operation block 3904, which includes generating a first time-varying magnetic field via movement of a magnetic element in each of a plurality of magneto-mechanical oscillators under the influence of a second time-varying magnetic field, the magnetic element disposed on a holder connected to a first base support element on a substrate by a first beam. For a wireless power transmitter, the second magnetic field may be a magnetic field generated by passing an alternating current through an excitation circuit, while the first magnetic field may be a magnetic field induced by the motion of the magnetic elements in each of the plurality of oscillators under the influence of the first magnetic field in the transmitter.

For wireless power receivers, the flowchart 2900 may begin at block 3904 and advance to block 3906, which includes generating an electrical current for powering or charging a load by a power extraction circuit under the influence of the second magnetic field. In some implementations, the power extraction circuit includes at least one coil surrounding at least a portion of the plurality of oscillators. For a wireless power receiver, the second magnetic field may be a magnetic field generated by a wireless power transmitter, while the first magnetic field may be a magnetic field induced by the motion of the magnetic elements in each of the plurality of oscillators under the influence of the first magnetic field in the receiver. Such an implementation may correspond to the torsional hinge magneto-mechanical oscillators as previously described in connection with FIGS. 21-28. Where the holder is also connected to a second base support element by a second beam, some implementations may correspond to the torsional double hinge oscillators as previously described in connection with FIGS. 18-20 and 25-28.

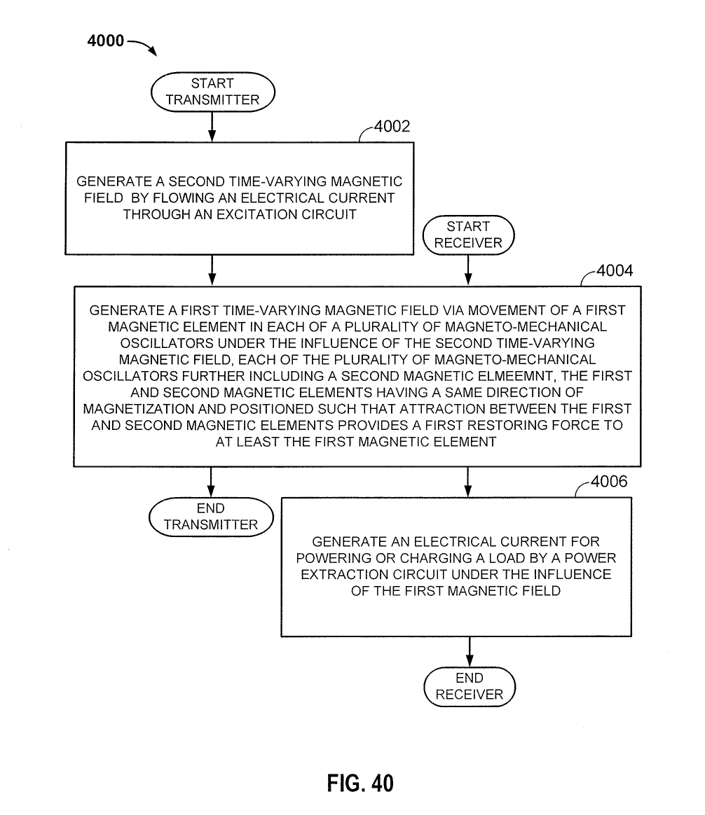

FIG. 40 is a flowchart 4000 of a method of transferring power wirelessly, in accordance with some other exemplary implementations. In some implementations, one or more of the blocks (e.g., 4002, 4004) in flowchart 4000 may be performed by a wireless power transmitter, while one or more blocks (e.g., 4004, 4006) may be performed by a wireless power receiver. Although the flowchart 4000 is described herein with reference to a particular order, in various implementations, blocks herein may be performed in a different order, or omitted, and additional blocks may be added.

For wireless power transmitters, the flowchart 4000 may begin with operation block 4002, which includes generating a second time-varying magnetic field by flowing an electrical current through an excitation circuit. In some implementations, the excitation circuit comprises at least one coil surrounding at least a portion of a plurality of magneto-mechanical oscillators. The flowchart 4000 may then advance to operation block 4004, which includes generating a first time-varying magnetic field having the excitation frequency via movement of a first magnetic element in each of a plurality of magneto-mechanical oscillators under the influence of a second time-varying magnetic field. Each of the plurality of magneto-mechanical oscillators further including a second element. The first and second magnetic elements have a same direction of magnetization and are positioned such that attraction between the first and second magnetic elements provides a first restoring force to at least the first magnetic element. For a wireless power transmitter, the second magnetic field may be a magnetic field generated by passing an alternating current through an excitation circuit, while the first magnetic field may be a magnetic field induced by the motion of the magnetic elements in each of the plurality of oscillators under the influence of the second magnetic field in the transmitter.

For wireless power receivers, the flowchart 4000 may begin at block 4004 and advance to block 4006, which includes generating an electrical current for powering or charging a load by a power extraction circuit under the influence of the second magnetic field. In some implementations, the power extraction circuit including at least one coil surrounding at least a portion of the plurality of oscillators. For a wireless power receiver, the second magnetic field may be a magnetic field generated by a wireless power transmitter, while the first magnetic field may be a magnetic field induced by the motion of the magnetic elements in each of the plurality of oscillators under the influence of the second magnetic field in the receiver. Such an implementation may correspond to the partially levitating magneto-mechanical oscillators as previously described in connection with FIGS. 29-31.

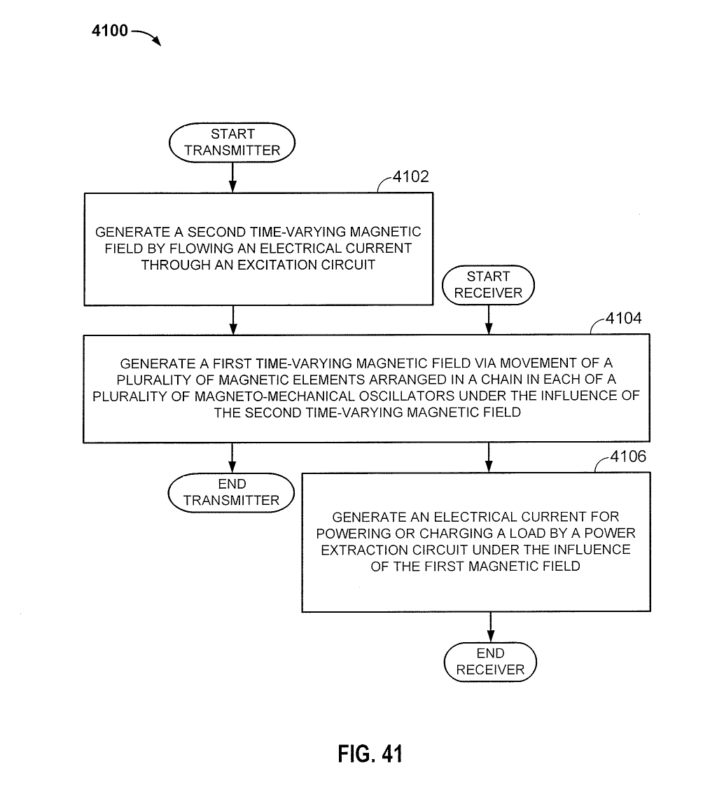

FIG. 41 is a flowchart 4100 of a method of transmitting power wirelessly, in accordance with some other exemplary implementations. In some implementations, one or more of the blocks (e.g., 4102, 4104) in flowchart 4100 may be performed by a wireless power transmitter, while one or more blocks (e.g., 41014, 4106) may be performed by a wireless power receiver. Although the flowchart 4100 is described herein with reference to a particular order, in various implementations, blocks herein may be performed in a different order, or omitted, and additional blocks may be added.

For wireless power transmitters, the flowchart 4100 may begin with operation block 4102, which includes generating a second time-varying magnetic field by flowing an electrical current through an excitation circuit. In some implementations, the excitation circuit comprises at least one coil surrounding at least a portion of a plurality of magneto-mechanical oscillators. The flowchart 4100 may then advance to operation block 4104, which includes generating a first time-varying magnetic field via movement of a plurality of magnetic elements arranged in a chain in each of a plurality of magneto-mechanical oscillators under the influence of a second time-varying magnetic field. For a wireless power transmitter, the second magnetic field may be a magnetic field generated by passing an alternating current through an excitation circuit, while the first magnetic field may be a magnetic field induced by the motion of the magnetic elements in each of the plurality of oscillators under the influence of the second magnetic field in the transmitter.

For wireless power receivers, the flowchart 4100 may begin at block 4104 and advance to block 4106, which includes generating an electrical current for powering or charging a load by a power extraction circuit under the influence of the second magnetic field, the power extraction circuit including at least one coil surrounding at least a portion of the plurality of oscillators. For a wireless power receiver, the first magnetic field may be a magnetic field generated by a wireless power transmitter, while the second magnetic field may be a magnetic field induced by the motion of the magnetic elements in each of the plurality of oscillators under the influence of the first magnetic field in the receiver. Such an implementation may correspond to the magneto-mechanical chain oscillators as previously described in connection with FIGS. 32-37.

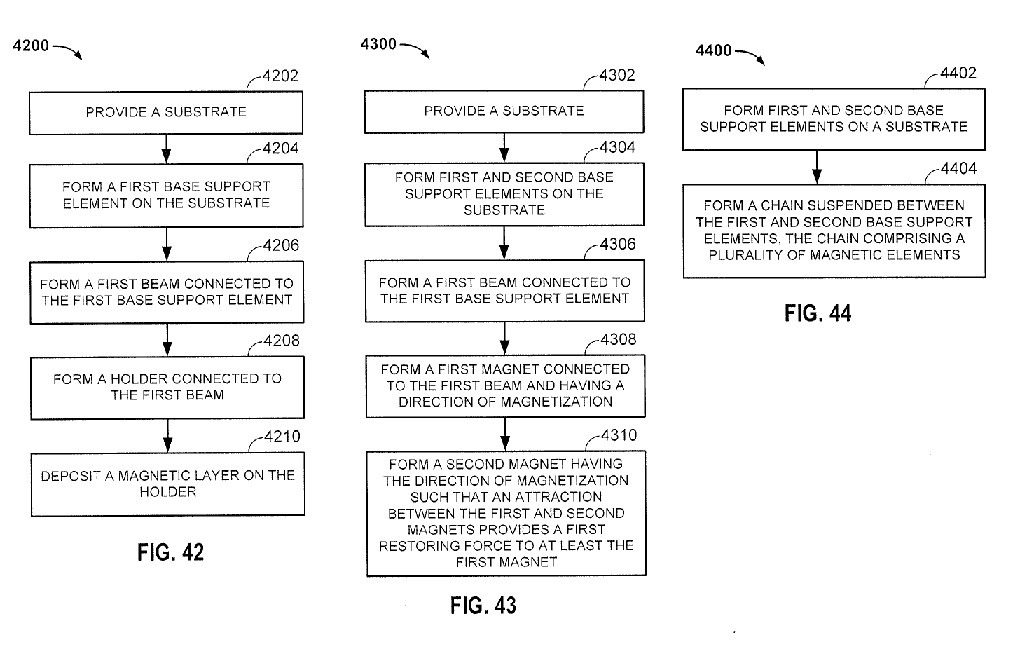

FIG. 42 is a flowchart 4200 of a method for fabricating a plurality of magneto-mechanical oscillators, in accordance with some exemplary implementations. The flowchart 4200 may represent a method for fabricating oscillators as shown in either of FIG. 18 or 19, as well as any 2- or 3-dimensional array of such oscillators. Although the flowchart 4200 is described herein with reference to a particular order, in various implementations, blocks herein may be performed in a different order, or omitted, and additional blocks may be added. Unless otherwise stated, any operation including the term “form” or “deposit” may be understood to mean depositing a suitable material utilizing any of physical vapor deposition (PVD), chemical vapor deposition (CVD), electro-deposition, or etching already present materials utilizing micro-structuring methods such as photolithography and etching, although other methods of deposition and etching may also be utilized. Operation blocks 4202-4210 may also be carried out for each of a plurality of magneto-mechanical oscillators in a 2-dimensional array, for example, as shown in FIGS. 20 and 22. In such implementations, each of operations blocks 4202-4210 may be performed in such a way so as to result in the “nested” arrangements as shown in FIGS. 20 and 22.

The flowchart 4200 may begin with operation block 4202, which includes providing a substrate. In some implementations, the substrate may be pre-formed. In other implementations, the substrate may be actively grown utilizing any of PVD, CVD, or electro-deposition, for example, although other processes may be utilized. The substrate may be made of any suitable material including but not limited to silicon, silicon carbide, silicon nitride, sapphire (Al₂O₃), or diamond. The flowchart 4200 may then advance to operation block 4204.

Operation block 4204 includes forming a first base support element on the substrate. The first base support element may be made of the same material as the substrate or a different material, depending on the implementation. The flowchart 4200 may then advance to operation block 4206.

In some implementations, such as when fabricating oscillators shown in FIGS. 18 and 19, a second base support element may be formed on the substrate. The second base support element may be formed of the same material as the first base support element.

Operation block 4206 includes forming a first beam connected to the first base support element. The first beam may be made of the same material as the substrate and/or the first base support element, or of a different material, depending on the implementation. The flowchart 4200 may then advance to operation block 4208.

In some implementations, such as when fabricating oscillators shown in FIGS. 18 and 19, a second beam may be formed connected to the second support element. The second beam may be made of the same material as the substrate and/or the second base support element, or of a different material, depending on the implementation.

Operation block 4208 includes forming a holder connected to the first beam. In some implementations, the holder may be made of the same or a different material as the first beam. In some implementations, where a second base support element and a second beam are formed, the holder may also be connected to the second beam. The flowchart 4200 may then advance to operation block 4210.

Operation block 4210 includes depositing a magnetic element on the holder. The magnetic element may comprise a ferromagnetic film or layer having a high remanence and, preferably, high coercivity, e.g., NdFeB, SmCo, or other magnetic materials. They may be deposited utilizing sputtering, pulsed laser deposition, electro-deposition, or any other suitable deposition process. Once a 2-dimensional array of oscillators is fabricated according to blocks 4202-4210 above, a 3-dimensional array may be formed by repeating blocks 4202-4210 (or blocks 4204-4210) for another 2-dimensional array substantially aligned with, or offset in one or more directions from, the previously fabricated 2-dimensional array, as previously described in connection with FIGS. 25-28.

FIG. 43 is a flowchart 4300 of a method for fabricating a plurality of magneto-mechanical oscillators, in accordance with some other exemplary implementations. The flowchart 4300 may represent a method for fabricating oscillators as shown in FIGS. 29 and 31, as well as any 2- or 3-dimensional array of such oscillators. Although the flowchart 4300 is described herein with reference to a particular order, in various implementations, blocks herein may be performed in a different order, or omitted, and additional blocks may be added. Unless otherwise stated, any operation including the term “form” or “deposit” may be understood to mean depositing a suitable material utilizing any of PVD, CVD, electro-deposition, or etching already present materials utilizing micro-structuring methods such as photolithography and etching, although other methods of deposition and etching may also be utilized. Operation blocks 4302-4310 may be carried out for each of a plurality of magneto-mechanical oscillators in a 2-dimensional array, for example, as shown in FIG. 30.

The flowchart 4300 may begin with operation block 4302, which includes providing a substrate, as previously described in connection with FIG. 42. The flowchart 4300 may then advance to operation block 4304.

Operation block 4304 includes forming first and second base support elements on the substrate. The first and second base support elements may be made of the same material as the substrate or a different material, depending on the implementation. The flowchart 4300 may then advance to operation block 4306.

Operation block 4306 includes forming a first beam connected to the first base support element. The first beam may be made of the same material as the substrate and/or the first base support element, or of a different material, depending on the implementation. The flowchart 4300 may then advance to operation block 4308.

In some implementations, such as when fabricating oscillators shown in FIGS. 29 and 30, a second beam may be formed connected to the second support element. The second beam may be made of the same material as the substrate, as the first base support element, or of a different material depending on the implementation.

Operation block 4308 includes forming a first magnetic element connected to the first beam and having a direction of magnetization. In some implementations, the direction of magnetization may be in a direction parallel to the axis through the first beam and the first magnetic element. The first magnetic element may comprise a ferromagnetic element having a high remanence and, preferably, high coercivity, e.g., NdFeB, SmCo, or other magnetic materials. They may be deposited utilizing sputtering, pulsed laser deposition, electro-deposition, or any other suitable deposition process. The flowchart 4300 may then advance to operation block 4310.

Operation block 4310 includes forming a second magnetic element having the direction of magnetization such that an attraction between the first and second magnetic elements provides a first restoring force to at least the first magnetic element. The second magnetic element may be formed similarly to the first magnetic element and may have the same direction of magnetization such that opposite poles of the first and second magnetic elements are adjacent to one another on one side of the first and second magnets. Where the oscillators are similar to those shown in FIG. 29, the attraction between the first and second magnetic elements will provide a first restoring force to both the first and second magnets. Where the oscillators are similar to those shown in FIG. 31, the attraction between the first and second magnetic elements will provide a first restoring force to the first magnetic element, since the second magnetic element is fixed by and anchored to the second base support element. As previously described, the above operations blocks 4302-4310 may be repeated for each of a plurality of oscillators to form a 2-dimensional array of oscillators. Furthermore, once a 2-dimensional array of oscillators is fabricated according to repetition of the blocks 4302-4310 above, a 3-dimensional array may be formed by repeating blocks 4302-4310 (or blocks 4304-4310) to fabricate another 2-dimensional array substantially aligned with, or offset in one or more directions from, the previously fabricated 2-dimensional array, as previously described in connection with FIG. 25-28 or 30.

FIG. 44 is a flowchart 4400 of a method for fabricating a plurality of magneto-mechanical oscillators, in accordance with some other exemplary implementations. The flowchart 4400 may represent a method for fabricating oscillators as shown in FIGS. 32, 33 and 36, as well as any 2- or 3-dimensional array of such oscillators, as shown in FIGS. 34, 35 and 37. Although the flowchart 4400 is described herein with reference to a particular order, in various implementations, blocks herein may be performed in a different order, or omitted, and additional blocks may be added. Unless otherwise stated, any operation including the term “form” or “deposit” may be understood to mean depositing a suitable material utilizing any of PVD, CVD, electro-deposition, or etching already present materials utilizing micro-structuring methods such as photolithography and etching, although other methods of deposition and etching may also be utilized. Operation blocks 4402-4404 may be carried out for each of a plurality of magneto-mechanical oscillators in a 2-dimensional array, for example, as shown in FIG. 34.

The flowchart 4400 may begin with operation block 4402, which includes forming first and second base support elements on a substrate. The first and second base support elements may be made of the same material as a substrate or a different material, depending on the implementation. The flowchart 4400 may then advance to operation block 4404.

Operation block 4404 includes forming a chain suspended between the first and second base support elements, the chain comprising a plurality of magnetic elements. In some implementations, such as those shown in FIG. 32, the chain may be formed of first and second beams 3206/3208 connected to the first and second base support elements 3202/3204, respectively. A plurality of magnetic elements 3210a-3210d may be connected to one another by a plurality of rigid non-metallic spacers. The plurality of connected magnetic elements 3210a-3210d may be fabricated and suspended between the first and second beams 3206/3208 to form the chain.

In some other implementations, as previously described in connection with FIG. 33, rather than utilizing first and second beams, a string may be formed that passes through and is anchored to the plurality of magnetic elements. As previously described, two or more strings, each having first ends anchored a predetermined distance from one another to the first base support element, and having second ends anchored a predetermined distance from one another to the second base support element. Both strings pass through and are anchored to the plurality of magnetic elements such that torsion in the strings provides the restoring force for the plurality of magnetic elements.

In yet other implementations, such as those shown in FIG. 36, the string may be formed as a heterogeneous magneto-elastic string. In some implementations, the string 3606 may be fabricated by extrusion of a melt comprising a mix of elastic (e.g., polyamide) and ferromagnetic components (e.g., ferromagnetic particles). The ferromagnetic particles may each have a direction of magnetization such that the chain exhibits a diametric direction of magnetization. Such a diametric direction of magnetization may be achieved by subjecting the melt to a magnetic field to properly align the ferromagnetic particles during extrusion. In yet other implementations, rather than comprising a heterogeneous mixture of elastic and ferromagnetic components, the chain may comprise a homogeneous magnetic material that results in at least a portion (e.g., a majority) of the chain having a diametric direction of magnetization.

In certain implementations, the wirelessly transferred power is used for wirelessly charging an electronic device (e.g., wirelessly charging a mobile electronic device). In certain implementations, the wirelessly transferred power is used for wirelessly charging an energy-storage device (e.g., a battery) configured to power an electric device (e.g., an electric vehicle).

The various operations of methods described above may be performed by any suitable means capable of performing the operations, such as various hardware and/or software component(s), circuits, and/or module(s). Generally, any operations illustrated in the figures may be performed by corresponding functional means capable of performing the operations. For example, a power transmitter or receiver can comprise means for generating a second time-varying magnetic field having an excitation frequency by applying a first time-varying magnetic field having the excitation frequency to the means for generating the second time-varying magnetic field. The means for generating the second time-varying magnetic field can comprise a plurality of magneto-mechanical oscillators in which each magneto-mechanical oscillator of the plurality of magneto-mechanical oscillators has a mechanical resonant frequency substantially equal to the excitation frequency and is configured to generate the second magnetic field via movement of the oscillators under the influence of the first magnetic field.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, circuits, and algorithm steps described in connection with the implementations disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions should not be interpreted as causing a departure from the scope of the implementations of the invention.

The various illustrative blocks, modules, and circuits described in connection with the implementations disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm and functions described in connection with the implementations disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art. A storage medium is coupled to the processor such that the processor can read information from, and write information to, the storage medium. In the alternative, the storage medium may be integral to the processor. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer readable media. The processor and the storage medium may reside in an ASIC.

For purposes of summarizing the disclosure, certain aspects, advantages and novel features of the inventions have been described herein. It is to be understood that not necessarily all such advantages may be achieved in accordance with any particular implementation of the invention. Thus, the invention may be embodied or carried out in a manner that achieves or optimizes one advantage or group of advantages as taught herein without necessarily achieving other advantages as may be taught or suggested herein.

Various modifications of the above described implementations will be readily apparent, and the generic principles defined herein may be applied to other implementations without departing from the spirit or scope of the invention. Thus, the present invention is not intended to be limited to the implementations shown herein but is to be accorded the widest scope consistent with the principles and novel features disclosed herein.

What is claimed is:

1. An apparatus for transferring power wirelessly, comprising:
a plurality of magneto-mechanical oscillators, each oscillator comprising:
a first base support element disposed on a substrate;
a first beam connected to the first base support element;
a holder connected to the first beam; and
a magnetic element disposed on the holder and configured to generate a first time-varying magnetic field in response to movement of the magnetic element under influence of a second time-varying magnetic field.

2. The apparatus of claim 1, wherein each of the plurality of oscillators comprises:
a second base support element disposed on the substrate; and
a second beam connecting the holder to the second base support element.

3. The apparatus of claim 1, further comprising an excitation circuit configured to generate the second time-varying magnetic field by flowing an electrical current through at least one coil surrounding at least a portion of the plurality of oscillators.

4. The apparatus of claim 1, further comprising a power extraction circuit configured to provide an electrical current for powering or charging a load under the influence of the first time-varying magnetic field.

5. The apparatus of claim 1, wherein the first beam is configured to provide a restoring force to the magnetic element in response to rotation of the magnetic element.

6. The apparatus of claim 1, wherein the plurality of oscillators are arranged in at least one two-dimensional array comprising a plurality of nested rows of oscillators such that oscillators in a particular nested row are disposed in spaces between adjacent oscillators in an adjacent row.

7. The apparatus of claim 1, wherein the plurality of oscillators are arranged in a plurality of two-dimensional arrays arranged in a three-dimensional array.

8. The apparatus of claim 1, wherein each oscillator of the plurality of magneto-mechanical oscillators is configured to resonate at a frequency of the second time-varying magnetic field.

9. A method of transferring power wirelessly, the method comprising:
generating a first time-varying magnetic field via movement of a magnetic element in each of a plurality of magneto-mechanical oscillators under the influence of a second time-varying magnetic field, the magnetic element disposed on a holder connected to a first base support element on a substrate by a first beam.

10. The method of claim 9, wherein the holder is connected to a second base support element on the substrate by a second beam.

11. The method of claim 9, further comprising generating the second magnetic field by flowing an electrical current through an excitation circuit comprising at least one coil surrounding at least a portion of the plurality of oscillators.

12. The method of claim 9, further comprising generating an electrical current for powering or charging a load by a power extraction circuit under the influence of the first magnetic field.

13. The method of claim 9, further comprising applying a restoring force to the magnetic element in response to rotation of the magnetic element.

14. The method of claim 9, wherein the plurality of oscillators are arranged in at least one two-dimensional array comprising a plurality of nested rows of oscillators such that oscillators in a particular nested row are disposed in spaces between adjacent oscillators in an adjacent row.

15. The method of claim 9, wherein the plurality of oscillators are arranged in a plurality of two-dimensional arrays arranged in a three-dimensional array.

16. An apparatus for transferring power wirelessly, comprising:
a plurality of magneto-mechanical oscillators, each oscillator comprising:
first and second base support elements, each disposed on a substrate;
a first beam connected to the first base support element;
a first magnetic element connected to the first beam; and
a second magnetic element, the first and second magnetic elements having a same direction of magnetization and positioned such that an attraction between the first and second magnetic elements provides a first restoring force to at least the first magnetic element, and at least the first magnetic element configured to generate a first time-varying magnetic field under the influence of a second time-varying magnetic field.

17. The apparatus of claim 16, wherein at least the first magnetic element is levitated by the attraction between the first and second magnetic elements.

18. The apparatus of claim 16, wherein each of the plurality of oscillators comprises a second beam connecting the second magnetic element to the second base support element.

19. The apparatus of claim 16, further comprising an excitation circuit including at least one coil surrounding at least a portion of the plurality of oscillators, the excitation circuit configured to generate the second magnetic field by flowing an electrical current through the at least one coil.

20. The apparatus of claim 16, further comprising a power extraction circuit, the power extraction circuit configured to provide an electrical current for powering or charging a load under the influence of the first magnetic field.

21. The apparatus of claim 16, wherein the first beam is configured to provide a second restoring force to the first magnetic element during oscillation of the first magnetic element.

22. The apparatus of claim 16, wherein the plurality of oscillators are arranged in at least one of a two-dimensional array comprising a plurality of rows of oscillators or a three-dimensional array.

23. The apparatus of claim 16, wherein each oscillator of the plurality of magneto-mechanical oscillators is configured to resonate at a frequency of the second time-varying magnetic field.

24. A method of transferring power wirelessly, the method comprising:
generating a first time-varying magnetic field via movement of a first magnetic element in each of a plurality of magneto-mechanical oscillators under the influence of a second time-varying magnetic field, each of the plurality of magneto-mechanical oscillators further including a second magnetic element, the first and second magnetic elements having a same direction of magnetization and positioned such that an attraction between the first and second magnetic elements provides a first restoring force to at least the first magnetic element.

25. The method of claim 24, wherein at least the first magnetic element is levitated by the attraction between the first and second magnets.

26. The method of claim 24, wherein each of the plurality of oscillators comprises a second beam connecting the second magnetic element to the second base support element.

27. The method of claim 24, further comprising generating the second magnetic field by flowing an electrical current through at least one excitation circuit comprising at least one coil surrounding at least a portion of the plurality of oscillators.

28. The method of claim 24, further comprising generating an electrical current for powering or charging a load by a power extraction circuit under the influence of the second magnetic field.

29. The method of claim 24, further comprising applying a second restoring force to the first magnetic element during oscillation of the first magnetic element.

30. The method of claim 24, wherein the plurality of oscillators are arranged in at least one of a two-dimensional array comprising a plurality of rows of oscillators or a three-dimensional array.
